(19) United States
(12) Patent Application Publication
(10) Pub. No.: US 2026/0370220 A1
(43) Pub. Date: Nov. 19, 2026

(54) MULTI PULSE GATE DRIVING FOR POWER SWITCHES

(71) Applicant: The University of British Columbia, Vancouver (CA)

(72) Inventors: Jan HAMMER, Vancouver (CA); Martin ORDONEZ, Vancouver (CA); Ignacio Galiano ZURBRIGGEN, Vancouver (CA)

(21) Appl. No.: 19/656,937

(22) Filed: Apr. 23, 2026

Related U.S. Application Data
(63) Continuation of application No. PCT/CA2024/051420, filed on Oct. 25, 2024.
(60) Provisional application No. 63/546,027, filed on Oct. 27, 2023.

(51) Int. Cl. H03K 17/0412; H03K 17/14; H03K 17/16

(52) U.S. Cl. CPC H03K 17/04123; H03K 17/145; H03K 17/162

(57) ABSTRACT

A method for operating a semiconductor switching device having a gate capacitance to switch the device from a starting steady state to an ending steady comprises: applying a first voltage pulse to a gate of the device when the device is in the starting steady state; and applying a second voltage pulse to the gate after applying the first gate driving pulse. The second voltage pulse is applied during a transition of the device between the starting steady state and the ending steady state.

### CROSS-REFERENCE TO RELATED APPLICATIONS

This application is a continuation of Patent Cooperation Treaty (PCT) application No. PCT/CA2024/051420 having an international filing date of 25 Oct. 2024 which in turn claims priority from, and for the purposes of the United States of America the benefit under 35 U.S.C. § 119 in connection with, U.S. application No. 63/546,027 filed 27 Oct. 2023. All of the applications referred to in this paragraph are hereby incorporated herein by reference.

### FIELD

The present disclosure relates to semiconductor switching devices having a control terminal (e.g. a gate) with corresponding gage capacitance. Some embodiments provide systems and methods for driving a gate of a semiconductor transistor.

### BACKGROUND

Gate driving circuits are an important component in switched-mode power converters. Gate driving circuits control the power semiconductor transistor switching transition slew-rates. Slew-rates refer to the maximum rate of change of the transistor output voltage with respect to time, i.e., how quickly a transistor can respond to changes in input signals. Slew-rates influence many performance metrics in hard-switched applications, including efficiency, electromagnetic compatibility (EMC), electromagnetic interference (EMI), etc.

Conventional gate driving circuits for semiconductor switching devices (e.g. transistors) having a gate capacitance typically utilize single pulse (step function) signals through a gate resistor (RG) to control turn-ON and turn-OFF slew-rates and transients of the power switch. One drawback of the conventional single pulse gate driving circuits is the limitation of slew-rate due to parasitic inductances (L_{Par}). If R_{G} is selected to be insufficiently large, the gate driving circuit will be underdamped, resulting in relatively large amounts of EMI, significant gate voltage oscillations and corresponding risk of false turn-ON events. Accordingly, in conventional single pulse circuits, there is a desire to choose RG to be sufficiently large (to control the slew rate of the gate voltage and thereby reduce the amplitude of oscillations in gate voltage and lower the risk of false turn-ON events). However, if RG is selected to be too large and the gate driving circuit is too overdamped, this can result in lower slew rates (lower switching times) and larger switching losses, thereby reducing operational efficiency. The disadvantages of excessively overdamping are especially pronounced in high-frequency switching applications, where switching speed is correspondingly important.

FIG. 1A is a schematic diagram of a circuit 10 for driving the gate of an enhancement mode metal oxide semiconductor field-effect transistor (MOSFET) 12 utilizing a conventional gate driving circuit incorporating gate resistor RG. FIG. 1B shows plots 20A to 20E of various circuit parameters as well as the magnitude of the switching losses over time when a conventional single pulse gate driving signal 20 is applied to circuit 10 for both turn-ON and turn-OFF operations in both underdamped (shown in dark black) and overdamped (shown in grey-scale) situations.

MOSFET 12 comprises a drain terminal 11, a source terminal 13, a gate terminal 15, and diode 17 (which may be the internal body diode 17 of MOSFET 12 and/or an external diode 17). Circuit 10 is illustrated with driving switches Q₁ and Q₂ representative of a half-bridge circuit (the rest of which is not expressly shown). The voltage measured across source terminal 13 and gate terminal 15 is denoted as v_{GS} and referred to herein as gate-source voltage. The voltage measured across drain terminal 11 and source terminal 13 is denoted as v_{DS} and referred to herein as drain-source voltage. A gate capacitance between source terminal 13 and gate terminal 15 is denoted as Cᵢₛₛ. Capacitance Cᵢₛₛ is typically determined by the physical and electrical properties of the MOSFET. A driving voltage v_{DR} is the output of a gate-control voltage source 14, which in the FIG. 1A embodiment is half-bridge circuit (controlled by switches Q₁ and Q₂) and, in the illustrated embodiment, driving voltage v_{DR} is the voltage across Q₂. Parasitic inductance L_{Par} is present between the gate-control voltage source 14 (the switched terminal 16 of the half bridge defined by Q₁ and Q₂) and gate terminal 15. Inductance L_{Par} is not a specific element of circuit 10, but is instead parasitically present in any conductor with relative magnetic permeability (μᵣ) greater than zero (i.e. any conductor that creates a magnetic field when charge moves through the conductor). Sources of parasitic inductance L_{Par} may include, without limitation, physical conductors, such as semiconductor traces, PCB traces, electrical wiring, bonds, busbars and connectors, etc. To dampen the above-discussed undesired oscillation in v_{GS} due to the parasitic inductance L_{Par}, a gate resistor RG is typically connected in series between the gate-control voltage source 14 (switched terminal 16) and gate terminal 15 in conventional gate-driving circuits. In operation, when the value of gate-source voltage v_{GS} exceeds threshold voltage Vₜₕ (FIG. 1B), a drain current i_{D} starts flowing between drain terminal 11 and source terminal 13.

In the FIG. 1A embodiment, when driving voltage v_{DR} is applied in a single pulse step from some steady state voltage below the MOSFET threshold voltage Vₜₕ(typically 0v) to some suitable step amplitude greater than Vₜₕ, the voltage difference between driving voltage v_{DR} and gate-source voltage V_{GS} creates a current i_{G} that charges Cᵢₛₛ over some time period until v_{GS} becomes greater than Vₜₕ (a characteristic of MOSFET 12) and turns MOSFET 12 ON so that current i_{D} flows through MOSFET 12 from drain to source. The application of driving voltage v_{DR} may also be referred to as a gate driving signal herein. When driving voltage v_{DR} steps back down below Vₜₕ (typically, to 0v), gate capacitance Cᵢₛₛ discharges over some time period, reducing v_{GS} to a value below Vₜₕ to turn MOSFET 12 OFF and, in the steady state OFF condition, current i_{D} drops to zero.

Referring to FIG. 1B, values of circuit parameters including driving voltage v_{DR} (shown in plot 20A), gate-source voltage v_{GS} (shown in plot 20B), drain current i_{D} (shown in plot 20C), drain-source voltage v_{DS} (shown in plot 20D), and switching losses P_{SW} (shown in plot 20E) are shown over time for a turn-ON operation (an upward step of driving voltage v_{DR}) and a turn-OFF operation (a downward step of driving voltage v_{DR}) when circuit 10 is underdamped (dark black lines) corresponding to relatively low values of gate resistance RG and when circuit 10 is overdamped (grey scale lines) corresponding to relatively large values of gate resistance RG.

As shown in plots 20A-E of FIG. 1B, MOSFET 12 is initially in an OFF-state, when driving voltage v_{DR} is stepped up (i.e. a single pulse step from some steady state voltage below the MOSFET threshold voltage Vₜₕ (typically 0v) to some suitable step amplitude greater than Vₜₕ) in a turn-ON operation. The application of driving voltage v_{DR} causes a corresponding increase in the value of gate-source voltage v_{GS} as discussed above. As the value of gate-source voltage v_{GS} exceeds the threshold voltage Vₜₕ, current i_{D} starts to flow through MOSFET 12 as a conductive channel is formed between drain terminal 11 and source terminal 13. Current i_{D} increases until it reaches some terminal steady state ON value and, once i_{D} reaches its terminal steady state ON value, drain-source voltage v_{DS} decreases toward its terminal steady state value. Meanwhile, the value of drain-source voltage v_{DS} decreases to a relatively small value.

MOSFET 12 is initially in an ON (conducting) state when driving voltage v_{DR} s stepped down (i.e. a single pulse step from some suitable step amplitude above Vₜₕ to an amplitude lower than Vₜₕ (typically 0v)) in a turn-OFF operation, MOSFET 12 is initially in an ON (conducting) state. Applying driving voltage v_{DR} less than Vₜₕ causes a corresponding decrease in the value of gate-source voltage v_{GS}, as gate capacitance Cᵢₛₛ discharges. As gate-source voltage v_{GS} decreases, drain-source voltage v_{DS} increases and current i_{D} decreases until gate-source voltage V_{GS} falls below Vₜₕ and current i_{D} stops flowing through MOSFET 12. In the steady state OFF state, v_{GS} eventually settles to some value below Vₜₕ, i_{D} is zero and V_{DS} settles at some circuit-dependent voltage level.

Plots 20B-20E of FIG. 1B illustrate two conditions: the underdamped condition (shown in dark black lines) which corresponds to relatively large gate resistance R_{G}; and the overdamped condition (shown in grey lines) which corresponds to relatively small gate resistance RG. It can be observed from plot 20B, that there is significant oscillation in v_{GS} and corresponding voltage stress across MOSFET 12 in the underdamped condition. Plots 20B-20E show that this oscillation (if sufficiently large) can result in false turn-ON events during a turn-OFF operation. Such a false turn-ON event is shown at portion 21B of the v_{GS} plot 20B, where the oscillation in v_{GS} is of sufficient amplitude that the value of v_{GS} falls below and then climbs back above Vₜₕ during a turn-OFF operation and MOSFET 12 becomes undesirably conductive (see portion 21C of i_{D} curve 200 and portion 21D of drain-source voltage V_{DS} curve 20D). False turn-ONs may lead to excessive and undesirable power loss (as shown at portion 21D) of switching power P_{SW} curve 20D, overheating, and even short circuits, destructive failures of the semiconductor and/or component damage.

To avoid false turn-ON events and the associated problems, it is typically desirable to choose gate resistance RG to have a reasonable value greater than zero, but when gate resistance is large enough to create the overdamped condition, there are corresponding increases in transient times and switching power resulting in reduced efficiency. The relatively slow transients associated with overdamped condition are shown in regions 23B of the v_{GS} plot 20B, where v_{GS} takes a relatively long time to climb to its steady state level (in the turn-ON operation) and a relatively long time to fall back to zero (in the turn-OFF operation). Because of the slow rate of change of gate-source voltage v_{GS} in the overdamped condition, it takes longer (Δt) to transition between the ON and OFF states (see the transients of current i_{D} as shown at 23 C and voltage v_{DS} as shown at 23D). These longer transients, in turn, are associated with undesirable switching power P_{SW} losses as shown at 21E.

There is a general desire to provide simple-to-implement gate driving methods for semiconductor switching devices having control terminal capacitance (e.g. semiconductor transistors having gate capacitance) and circuits incorporating such methods which ameliorate one or more of the drawbacks of conventional gate driving methods, such as, by way of non-limiting example, those described above.

### SUMMARY

One aspect of the invention provides a method for operating a semiconductor switching device having a gate capacitance to switch the device from a starting steady state to an ending steady state that is different from the starting steady state. The method comprises: applying a first gate-driving voltage pulse to a gate of the device when the device is in the starting steady state, the first voltage pulse having a first effective amplitude a first pulse duration t_{A}; and applying a second gate-driving voltage pulse to the gate after applying the first gate driving pulse, the second gate-driving voltage pulse having a second effective amplitude and a second pulse duration. The second voltage pulse is applied during a transition of the device between the starting steady state and the ending steady state.

The first effective amplitude may cross from a starting state value that is below a threshold voltage Vₜₕ associated with the device to a first pulse value that is above the threshold voltage Vₜₕ. The second gate-driving voltage pulse has a second effective amplitude that may cross from an intermediate value that is below the threshold voltage Vₜₕ to a second pulse value that is above the threshold voltage Vₜₕ.

The first effective amplitude may cross from a starting state value that is above a threshold voltage Vₜₕ associated with the device to a first pulse value that is below the threshold voltage Vₜₕ. The second gate-driving voltage pulse has a second effective amplitude that may cross from an intermediate value that is above the threshold voltage Vₜₕ to a second pulse value that is below the threshold voltage Vₜₕ.

The intermediate value may be about equal to the starting state value.

The first pulse duration t_{A} may be less than a time that it takes for the device to reach the ending steady state. The second gate-driving pulse has a duration that may be sufficiently long for the device to reach the ending steady state during the second gate-driving pulse.

The method may comprise maintaining the gate-driving voltage at an intermediate value for a period of time t_{B} after a conclusion of the first gate-driving pulse and before applying the second gate-driving voltage pulse.

The first effective amplitude may be the same as the second effective amplitude.

The method may be applied to a turn-ON operation, where the device is non-conducting (e.g. between drain and source) in the starting steady state, the device is conducting (e.g. between drain and source) in the ending steady state, the starting state value and the intermediate value are less than the threshold voltage Vₜₕ and the first pulse value and the second pulse value are greater than the threshold voltage Vₜₕ.

The method may be applied to a turn-OFF operation, where the device is conducting (e.g. between drain and source) in the starting steady state, the device is non-conducting (e.g. between drain and source) in the ending steady state, the starting state value and the intermediate value are greater than the threshold voltage Vₜₕ and the first pulse value and the second pulse value are less than the threshold voltage Vₜₕ.

The method may comprise applying one or more additional gate-driving voltage pulses to the gate after applying the first gate driving pulse and prior to applying the second gate driving pulse. The one or more additional gate-driving pulses have the same pulse parameters (e.g. amplitude and duration) as the first pulse or different pulse parameters (e.g. amplitude and duration) from the first pulse. Temporal pulse-spacing between the first pulse, the one or more additional pulses and the second pulse may be the same or may be different.

Applying the first and second gate-driving pulses may comprise controlling a gate-control voltage source.

Controlling the gate-control voltage source may comprise controlling a half-bridge circuit having its switched terminal electrically connected to the gate.

The electrical connection between the switched terminal and the gate may be made by an electrically conductive connection wherein any resistance between the switched terminal and the gate is the inherent internal resistance of the electrically conductive connection, including, possibly, any internal driver and/or MOSFET connections of the half-bridge circuit. Any inductance between the switched terminal and the gate may be the inherent internal inductance Lₚₐᵣ of the electrically conductive connection, including, possibly, any internal driver and/or MOSFET connections of the half-bridge circuit.

Applying the first pulse may comprise controlling the half-bridge circuit to provide a pulse-width modulated (PWM) signal at the switched terminal and wherein the first effective amplitude is based on one or more of the parameters (e.g. pulse amplitude, frequency and/or duty cycle) of the PWM signal. The method may comprise controlling the half-bridge circuit to vary one or more of the parameters (e.g. pulse amplitude, frequency and/or duty cycle) of the PWM signal during the first pulse duration t_{A}.

Applying the second pulse may comprise controlling the half-bridge to clamp the voltage at the switched terminal to the second effective amplitude when a gate current i_{G} is at or near zero.

Controlling the gate-control voltage source may comprise controlling a full-bridge circuit.

The full-bridge circuit may have one of its switched terminals electrically connected to the gate. The electrical connection between the one of the switched terminals and the gate may be made by an electrically conductive connection wherein any resistance between the one of the switched terminals and the gate is the inherent internal resistance of the electrically conductive connection, including, possibly, any internal driver and/or MOSFET connections of the full-bridge circuit. Any inductance between the one of the switched terminals and the gate may be the inherent internal inductance Lₚₐᵣ of the electrically conductive connection, including, possibly, any internal driver and/or MOSFET connections of the full-bridge circuit.

The full-bridge circuit may comprise an inductor LG connected between the one of the switched terminals and a second one of the switched terminals of the full-bridge.

Applying the first gate-driving pulse may comprise: controlling the full-bridge to charge the inductor LG prior to applying the first pulse, and controlling the full-bridge to cause the inductor LG to act as a current source when the first pulse is applied. Applying the second pulse may comprise controlling the full-bridge to clamp the voltage at the one of the switched terminals to the second effective amplitude when a gate current i_{G} is at or near zero.

Applying the first pulse may comprise controlling the full-bridge circuit to provide a pulse-width modulated (PWM) signal at the second one of the switched terminals and wherein the first effective amplitude is based on one or more of the parameters (e.g. pulse amplitude, frequency and/or duty cycle) of the PWM signal. The method may comprise controlling the full-bridge circuit to vary one or more of the parameters (e.g. pulse amplitude, frequency and/or duty cycle) of the PWM signal during the first pulse duration t_{A}. Applying the second pulse may comprise controlling the full-bridge to clamp the voltage at the one of the switched terminals to the second effective amplitude when a gate current i_{G} is at or near zero.

The method may comprise repeatedly applying the method to switch the device from the starting state to the ending state and to switch the device from the ending state back to the starting state.

The repeated application of the method may be used in one of: a switch-mode power supply; a digital communication circuit; a discrete amplifier; a signal conditioning circuit; a LED drive; and a digital clock.

The method may comprise: sensing a value of at least one of a voltage at a node of the device and a current through a node of the device; and adjusting one or more parameters of at least one of the first gate-driving pulse and the second gate-driving pulse based at least in part on the sensed value. The node of the device may be one of a gate, a source or a drain of a transistor.

The method may comprise: sensing a temperature correlated with a temperature of the device; and adjusting one or more parameters of at least one of the first gate-driving pulse and the second gate-driving pulse based at least in part on the sensed value.

Adjusting the one or more parameters of at least one of the first gate-driving pulse and the second gate-driving pulse based at least in part on the sensed value may be performed by a controller. The controller may be configured to implement a control algorithm based at least in part on a desired value for the sensed value.

The one or more parameters of the at least one of the first gate-driving pulse and the second gate-driving pulse may comprise: the first pulse duration t_{A}; the first effective amplitude; a period of time t_{B} after a conclusion of the first gate-driving pulse and before applying the second gate-driving voltage pulse during which the gate-driving voltage is maintained at the intermediate value; and/or the second effective amplitude.

Applying the first gate-driving pulse may comprise applying a first series of pulse-width modulated (PWM) voltage pulses to the gate, the first series of pulse-width modulated voltage pulses having first PWM parameters (e.g. a first PWM frequency, a first PWM duty cycle and/or a first PWM amplitude) which achieve the first effective amplitude. The one or more parameters of the at least one of the first gate-driving pulse and the second gate-driving pulse may comprise at least one of the first PWM parameters.

Applying the second gate-driving pulse may comprise applying a second series of pulse-width modulated (PWM) voltage pulses to the gate, the second series of pulse-width modulated voltage pulses having second PWM parameters (e.g. a second PWM frequency, a second PWM duty cycle and/or a second PWM amplitude) which achieve the second effective amplitude. The one or more parameters of the at least one of the first gate-driving pulse and the second gate-driving pulse may comprise at least one of the second PWM parameters.

Another aspect of the invention provides a circuit for operating a semiconductor switching device having a gate capacitance to switch the device from a starting steady state to an ending steady state that is different from the starting steady state. The circuit comprises: a gate-control voltage source connected to a gate of the transistor by an electrically conductive (e.g. metal) connection between an output of the gate-control voltage source and the gate; and a controller connected to the gate-control voltage source, the controller configured to: cause the gate-control voltage source to apply a first gate-driving voltage pulse to a gate of the device when the device is in the starting steady state, the first voltage pulse having a first effective amplitude a first pulse duration t_{A}; and cause the gate-control voltage source to apply a second gate-driving voltage pulse to the gate after applying the first gate driving pulse, the second gate-driving voltage pulse having a second effective amplitude and a second pulse duration. The second voltage pulse is applied during a transition of the device between the starting steady state and the ending steady state.

The gate-control voltage source may comprise a half-bridge circuit comprising a pair of switches and a switched terminal therebetween, the switched terminal electrically connected to the gate by the electrically conductive connection.

Any resistance between the switched terminal and the gate may be the inherent internal resistance of the electrically conductive connection, including, possibly, any internal driver and/or MOSFET connections of the half-bridge circuit. Any inductance between the switched terminal and the gate may be the inherent internal inductance Lₚₐᵣ of the electrically conductive connection, including, possibly, any internal driver and/or MOSFET connections of the half-bridge circuit.

The controller may be configured to cause the gate-control voltage source to apply the first pulse by controlling the switches of the half-bridge circuit to provide a pulse-width modulated (PWM) signal at the switched terminal and wherein the first effective amplitude is based on one or more of the parameters (e.g. pulse amplitude, frequency and/or duty cycle) of the PWM signal. The controller may be configured to control the switches of the half-bridge circuit to vary one or more of the parameters (e.g. pulse amplitude, frequency and/or duty cycle) of the PWM signal during the first pulse duration t_{A}.

The controller may be configured to cause the gate-control voltage source to apply the second pulse by controlling the switches of the half-bridge circuit to clamp the voltage at the switched terminal to the second effective amplitude when a gate current i_{G} is at or near zero.

The gate-control voltage source may comprise a full-bridge circuit comprising a pair of branches, each branch comprising a pair of switches and a switched terminal therebetween. One of the switched terminals of the full-bridge circuit may be electrically connected to the gate. The electrical connection between the one of the switched terminals and the gate may be made by an electrically conductive connection wherein any resistance between the one of the switched terminals and the gate may be the inherent internal resistance of the electrically conductive connection, including, possibly, any internal driver and/or MOSFET connections of the full-bridge circuit. Any inductance between the one of the switched terminals and the gate may be the inherent internal inductance Lₚₐᵣ of the electrically conductive connection, including, possibly, any internal driver and/or MOSFET connections of the full-bridge circuit.

The full-bridge circuit may comprise an inductor LG connected between the switched terminals of the full-bridge.

The controller may be configured to cause the gate-control voltage source to apply the first pulse by controlling the switches of the full-bridge to charge the inductor L_{G} prior to applying the first pulse, and controlling the switches of the full-bridge to cause the inductor LG to act as a current source when the first pulse is applied. The controller may be configured to cause the gate-control voltage source to apply the second pulse by controlling the switches of the full-bridge to clamp the voltage at the one of the switched terminals to the second effective amplitude when a gate current i_{G} is at or near zero.

The controller may be configured to cause the gate-control voltage source to apply the first pulse by controlling the switches of the full-bridge circuit to provide a pulse-width modulated (PWM) signal at the second one of the switched terminals and wherein the first effective amplitude is based on one or more of the parameters (e.g. pulse amplitude, frequency and/or duty cycle) of the PWM signal. The controller may be configured to control the switches of the full-bridge circuit to vary one or more of the parameters (e.g. pulse amplitude, frequency and/or duty cycle) of the PWM signal during the first pulse duration t_{A}. The controller may be configured to cause the gate-control voltage source to apply the second pulse by controlling the switches of the full-bridge to clamp the voltage at the one of the switched terminals to the second effective amplitude when a gate current i_{G} is at or near zero.

The first effective amplitude may cross from a starting state value that is below a threshold voltage Vₜₕ associated with the device to a first pulse value that is above the threshold voltage Vₜₕ. The second gate-driving voltage pulse has a second effective amplitude that may cross from an intermediate value that is below the threshold voltage Vₜₕ to a second pulse value that is above the threshold voltage Vₜₕ.

The first effective amplitude may cross from a starting state value that is above a threshold voltage Vₜₕ associated with the device to a first pulse value that is below the threshold voltage Vₜₕ. The second gate-driving voltage pulse has a second effective amplitude that may cross from an intermediate value that is above the threshold voltage Vₜₕ to a second pulse value that is below the threshold voltage Vₜₕ.

The intermediate value may be about equal to the starting state value.

The controller may configured to control the first pulse duration t_{A} to be less than a time that it takes for the device to reach the ending steady state. The controller may be configured to control the second gate-driving pulse have a duration that is sufficiently long for the device to reach the ending steady state during the second gate-driving pulse.

The controller may be configured to maintain the gate-driving voltage at an intermediate value for a period of time t_{B} after a conclusion of the first gate-driving pulse and before causing the gate-control voltage source to apply the second gate-driving voltage pulse.

The first effective amplitude may be the same as the second effective amplitude.

The controller may be configured to implement a turn-ON operation, where the device is non-conducting (e.g. between drain and source) in the starting steady state, the device is conducting (e.g. between drain and source) in the ending steady state, the starting state value and the intermediate value are less than the threshold voltage Vₜₕ and the first pulse value and the second pulse value are greater than the threshold voltage Vₜₕ.

The controller may be configured to implement a turn-OFF operation, where the device is conducting (e.g. between drain and source) in the starting steady state, the device is non-conducting (e.g. between drain and source) in the ending steady state, the starting state value and the intermediate value are greater than the threshold voltage Vₜₕ and the first pulse value and the second pulse value are less than the threshold voltage Vₜₕ.

The controller may be configured to apply one or more additional gate-driving voltage pulses to the gate after applying the first gate driving pulse and prior to applying the second gate driving pulse. The one or more additional gate-driving pulses have the same pulse parameters (e.g. amplitude and duration) as the first pulse or different pulse parameters (e.g. amplitude and duration) from the first pulse.

Temporal pulse-spacing between the first pulse, the one or more additional pulses and the second pulse may be the same or different.

The controller may be configured to repeatedly switch the device from the starting state to the ending state and to switch the device from the ending state back to the starting state.

The circuit may be used in one of: a switch-mode power supply; a digital communication circuit; a discrete amplifier; a signal conditioning circuit; a LED drive; and a digital clock.

The circuit may comprise a sensor connected to sense a value of at least one of a voltage at a node of the device and a current through a node of the device. The controller may be configured to adjust one or more parameters of at least one of the first gate-driving pulse and the second gate-driving pulse based at least in part on the sensed value. The node of the device may be one of a gate, a source or a drain of a transistor.

The circuit may comprise a sensor connected to sense a temperature correlated with a temperature of the device. The controller may be configured to adjust one or more parameters of at least one of the first gate-driving pulse and the second gate-driving pulse based at least in part on the sensed value.

The controller may be configured to implement a control algorithm based at least in part on a desired value for the sensed value.

The one or more parameters of the at least one of the first gate-driving pulse and the second gate-driving pulse may comprise: the first pulse duration t_{A}; the first effective amplitude; a period of time t_{B} after a conclusion of the first gate-driving pulse and before applying the second gate-driving voltage pulse during which the gate-driving voltage is maintained at the intermediate value; and/or the second effective amplitude.

The controller may be configured to apply the first gate-driving pulse by applying a first series of pulse-width modulated (PWM) voltage pulses to the gate, the first series of pulse-width modulated voltage pulses having first PWM parameters (e.g. a first PWM frequency, a first PWM duty cycle and/or a first PWM amplitude) which achieve the first effective amplitude. The one or more parameters of the at least one of the first gate-driving pulse and the second gate-driving pulse may comprise at least one of the first PWM parameters.

The controller may be configured to apply the second gate-driving pulse by applying a second series of pulse-width modulated (PWM) voltage pulses to the gate, the second series of pulse-width modulated voltage pulses having second PWM parameters (e.g. a second PWM frequency, a second PWM duty cycle and/or a second PWM amplitude) which achieve the second effective amplitude. The one or more parameters of the at least one of the first gate-driving pulse and the second gate-driving pulse may comprise at least one of the second PWM parameters.

Other aspects of the invention provide apparatus having any new and inventive feature, combination of features, or sub-combination of features as described herein.

Other aspect of the invention provide methods having any new and inventive steps, acts, combination of steps and/or acts or sub-combination of steps and/or acts as described herein.

It is emphasized that the invention relates to all combinations of the above features, even if these are recited in different claims.

Further aspects and example embodiments are illustrated in the accompanying drawings and/or described in the following description.

### BRIEF DESCRIPTION OF THE DRAWINGS

The accompanying drawings illustrate non-limiting example embodiments of the invention.

FIG. 1A is a schematic circuit diagram for driving an enhancement mode metal oxide semiconductor field-effect transistor (MOSFET) utilizing a conventional gate driving circuit incorporating a gate resistance RG.

FIG. 1B shows plots of various circuit parameters as well as the magnitude of the switching losses over time when a conventional single pulse (step function) gate-driving signal v_{DR} is applied to the FIG. 1A circuit for both turn-ON and turn-OFF operations in both underdamped and overdamped situations.

FIG. 2A is a schematic circuit diagram of an enhancement mode metal oxide semiconductor field-effect transistor (MOSFET) suitable for use with a multi-pulse gate-driving methodology according to a particular embodiment of the invention.

FIG. 2B shows plots of various circuit parameters as well as the magnitude of the switching losses over time when a multi-pulse gate-driving signal v_{DR} is applied to the FIG. 2A circuit for both turn-ON and turn-OFF operations.

FIG. 3 is a flowchart of a method for driving the gate of a semiconductor transistor having a gate capacitance according to an example embodiment.

FIG. 4A is a schematic circuit diagram of an enhancement mode metal oxide semiconductor field-effect transistor (MOSFET) and a corresponding gate-driving circuit suitable for use with the multi-pulse gate-driving methodology of FIGS. 2A and 3 according to a particular embodiment of the invention. FIG. 4B shows a plurality of operational modes of the FIG. 4A gate-driving circuit 300. FIG. 4C shows a simplified equivalent gate-driving circuit corresponding to the FIG. 4A gate-driving circuit.

FIG. 5 shows a plurality of plots of various circuit parameters of the FIG. 4A gate-driving circuit during a turn-ON operation according to a particular embodiment.

FIG. 6A shows a normalized state plane plot during time period t_{A} shown in FIG. 5. FIG. 6B shows a normalized state plane plot 500B during time period t_{B} shown in FIG. 5.

FIG. 7 shows a plurality of plots of various circuit parameters of the FIG. 4A gate-driving circuit during a turn-OFF operation according to a particular embodiment.

FIG. 8A shows a normalized state plane plot during time period t_{A} shown in FIG. 7. FIG. 8B shows a normalized state plane plot 500B during time period t_{B} shown in FIG. 7.

FIG. 9 is a schematic illustration of a method for determining the parameters t_{A} and t_{B} according to particular embodiment including an optional fine turning adjustment method using an additional incremental time-adjustment parameter p.

FIGS. 10A, 10B, 10C (collectively, FIG. 10) illustrate a comparison of the traditional approach (using single step function gate-drive signal v_{DR} and a gate resistance RG) for the underdamped condition (FIG. 10A) and the overdamped condition (FIG. 10B) applied to the FIG. 1A circuit and the mutely-pulse approach shown in FIGS. 5, 7 applied to the circuit of FIG. 4A.

FIG. 11A is a schematic circuit diagram of full H-bridge (also known as a full-bridge or full H-bridge) configuration which can be used to provide a multi-pulse gate-driving methodology according to a particular embodiment of the invention which can operate in a number of operating modes. FIG. 11B is a schematic illustration of a number of circuit parameters of the FIG. 11A full-bridge circuit when operating in an operating mode A which is equivalent to the half-bridge configuration described elsewhere herein. FIG. 11C is a schematic illustration of a number of circuit parameters of the FIG. 11A full-bridge circuit when operating in an operating mode B.

FIG. 11D is a schematic illustration of a number of circuit parameters of the FIG. 11A full-bridge circuit when operating in an operating mode C. FIG. 11E is a schematic illustration of a number of circuit parameters of the FIG. 11A full-bridge circuit in an example implementation wherein a variation of PWM duty cycle is used during the first pulse of a turn-ON operation.

FIG. 12 is a schematic depiction of a closed loop system which involves measurement of one or more variables and feeding back this information to a controller which can be configured to implement a suitable control mechanism to adapt the multi-pulse parameters of the v_{DR} gate-driving pulses according to a particular embodiment.

FIGS. 13A, 13B and 13C (collectively FIG. 13) respectively depict a window comparator circuit implementing feedback according to a particular embodiment, waveforms for various parameters when the transferred charge is too low and waveforms for various parameters when the transferred charge is too high.

FIG. 14 is a flow chart illustrating a methodology 930 that may be used to implement the i_{G} feedback illustrated in the FIG. 13A circuit according to a particular embodiment.

### DETAILED DESCRIPTION

Throughout the following description, specific details are set forth in order to provide a more thorough understanding of the invention. However, the invention may be practiced without these particulars. In other instances, well known elements have not been shown or described in detail to avoid unnecessarily obscuring the invention. Accordingly, the specification and drawings are to be regarded in an illustrative, rather than a restrictive sense.

Various aspects of the invention provide gate driving circuits and associated control terminal (e.g. gate) driving methodologies involving the application of multi-pulse gate driving signals v_{DR} to control the switching operation a semiconductor switching device (e.g. a semiconductor) transistor. In some embodiments, these multi-pulse gate-driving signals are used to provide relatively fast transients (and corresponding switching power efficiency) when compared to the overdamped condition resulting from the gate resistance RG used in prior art techniques while reducing the amplitude of oscillation (and the corresponding risk of false turn-ON events) when compared to the underdamped condition resulting from the gate resistance RG used in prior art techniques.

Some aspects of the invention provide a method for operating a semiconductor switching device having a gate capacitance to switch the device from a starting steady state to an ending steady state. The method comprises: applying a first gate-driving voltage pulse to a gate of the device when the device is in the starting steady state, the first voltage pulse having a first effective amplitude a first pulse duration; and applying a second gate-driving voltage pulse to the gate after applying the first gate driving pulse, the second gate-driving voltage pulse having a second effective amplitude and a second pulse duration. The second voltage pulse may be applied during a transition of the device between the starting steady state and the ending steady state.

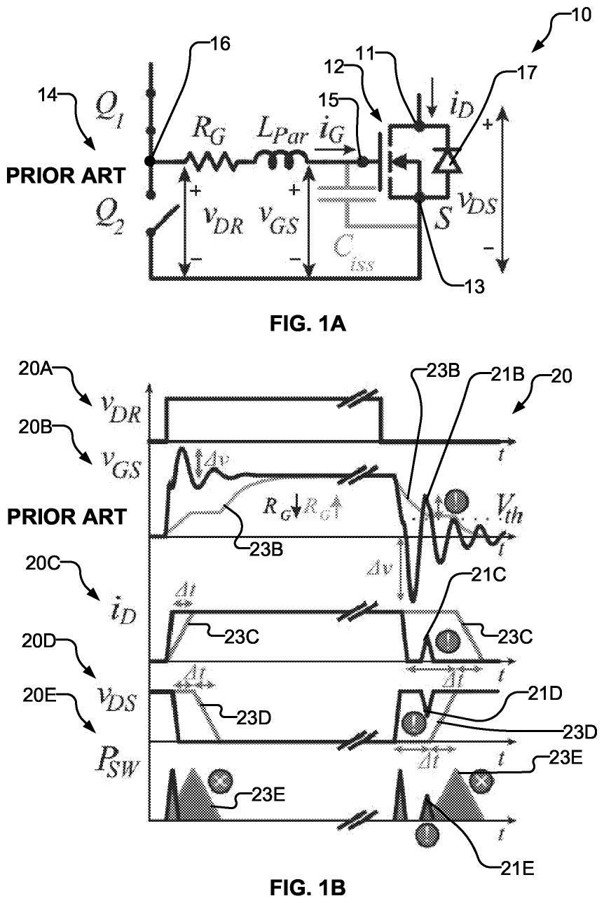

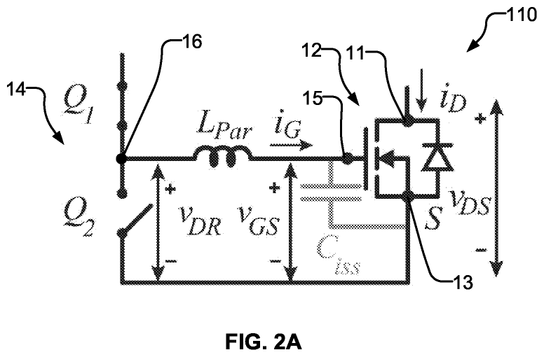

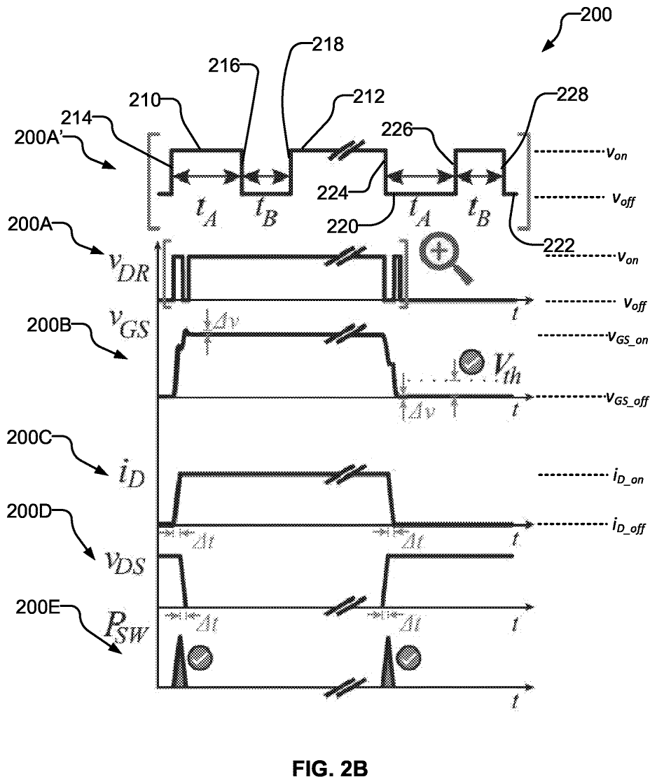

FIG. 2A is a schematic diagram of a circuit 110 for driving the gate of an enhancement mode MOSFET 12 suitable for use with a multi-pulse gate-driving methodology according to a particular embodiment of the invention. MOSFET 12 of and gate-control voltage source 14 circuit 110 may be the same as MOSFET 12 and gate-control voltage source 14 described above in connection with FIG. 1A. Circuit 110 differs from circuit 10 primarily in that circuit 110 dispenses with gate resistor RG between the switched half-bridge terminal 16 and gate 15 and, in a different approach, uses a multi-pulse gate driving signal v_{DR} described in more detail below. In some embodiments, switched half-bridge terminal 16 is connected to directly to gate node 15 by an electrically conductive (e.g. metal) connection—e.g. any resistance between half-bridge terminal 16 and gate node 15 is the inherent internal resistance of the electrically conductive connection (including, possibly, any internal driver and/or MOSFET connections (e.g. of gate-control voltage source 14 or the half-bridge circuit)) and inductance Lₚₐᵣ is the inherent or parasitic inductance of this conductive connection (including, possibly, any internal driver and/or MOSFET connections (e.g. of gate-driving voltage source 14 or the half-bridge)).

FIG. 2B shows plots of various circuit parameters as well as the magnitude of the switching losses over time when a multi-pulse gate-driving signal V_{DR} is applied to the FIG. 2A circuit 110 for both turn-ON and turn-OFF operations. In particular, in the illustrated embodiment, plot 200A shows a multi-pulse gate-driving signal v_{DR} comprising a plurality (e.g. two in the case of the illustrated embodiment of FIGS. 2A, 2B but optionally more than two) pulses for the turn-ON operation and a plurality (e.g. two in the case of the illustrated embodiment of FIGS. 2A, 2B but optionally more than two) pulses for a turn-OFF operation. Plot 200A′ shows expanded detail of the plot 200A multi-pulse gate-driving signal v_{DR} according to the particular multi-pulse profile of the illustrated embodiment.

Plot 200A′ illustrates a number of parameters vₒₙ, v_{off}, t_{A}, t_{B} which may be used to characterize the particular plot 200A multi-pulse gate-driving signal V_{DR}. In the particular case of the FIG. 2B embodiment, a turn-ON operation comprises a pair of pulses 210, 212 of the gate-driving signal V_{DR}, where each pulse 210, 212 has an amplitude ranging from v_{off} to von, where v_{off} is less than Vₜₕ (e.g. 0v) and vₒₙ is greater than Vₜₕ. First turn-ON pulse 210 comprises a rising edge 214 from v_{off} to von and a duration of t_{A} followed by a falling edge 216 where gate-driving signal V_{DR} steps back down from vₒₙ to v_{off}. After a period t_{B}, where gate-driving signal V_{DR} stays at v_{off}, second turn-ON pulse 212 has a rising edge 218 from v_{off} to vₒₙ and stays at vₒₙ for any suitable period for which it is desired that MOSFET 12 be in a conducting state.

Similarly, in the particular case of the FIG. 2B embodiment, a turn-OFF operation comprises a pair of pulses 220, 222 of the gate-driving signal V_{DR}, where each pulse 220, 222 has an amplitude ranging from vₒₙ to v_{off}, where v_{off} is less than Vₜₕ (e.g. 0v) and vₒₙ is greater than Vₜₕ. First turn-OFF pulse 220 comprises a falling edge 224 from vₒₙ to v_{off} and a duration of t_{A} followed by a rising edge 226 where gate-driving signal v_{DR} steps back up from v_{off} to vₒₙ. After a period t_{B}, where gate-driving signal v_{DR} stays at vₒₙ, second turn-ON pulse 212 has a falling edge 228 from vₒₙ to v_{off} and stays at v_{off} for any suitable period for which it is desired that MOSFET 12 be in a non-conducting state. In some embodiments, the multi-pulse parameters vₒₙ, v_{off}, t_{A}, t_{B} are the same for both the turn-ON operation and the turn-OFF operation, but this is not necessary. In some embodiments, one or more of these parameters is different as between the turn-ON operation and the turn-OFF operation.

As can be seen from plots 200B-200E in FIG. 2B, the multi-pulse gate-driving signal v_{DR} shown in plot 200A (when compared to the prior art single-pulse (step function) gate driving signal shown in FIGS. 1A, 1B) achieves reduced voltage stress and reduced oscillations in v_{GS}, while operating at high slew rates (fast transients) of current i_{D} and drain-source voltage V_{DS} with consequent low switching power P_{SW} losses. Also, because of the relatively low oscillation in v_{GS} (when compared to the prior art single-pulse (step function) gate driving signal shown in FIGS. 1A, 1B), there is relatively little risk of false turn-ON during the turn-OFF operation in contrast to the underdamped scenario shown in FIG. 1B.

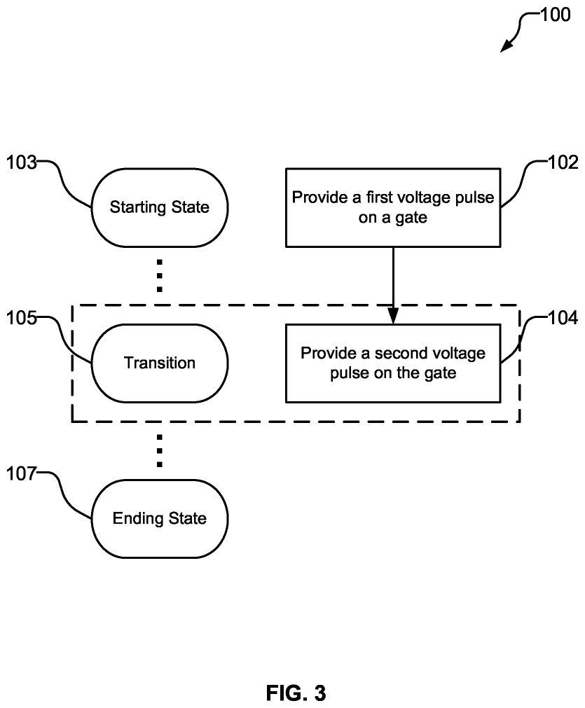

FIG. 3 is a flowchart of a method 100 for driving the control terminal of a semiconductor switching device (e.g. the gate of a semiconductor transistor) having a gate capacitance according to an example embodiment. The semiconductor switch controlled in accordance with method 100 may, for example, be MOSFFET 12 shown in FIGS. 2A, 2B although this is not necessary. Method 100 may be used to drive the control terminals (referred to herein as “gates” for brevity) of other semiconductor switching devices. By way of non-limiting example, such devices may include thyristors, transistors, such as gate turn-off Thyristors (GTO), MOS-controlled thyristors (MCT) and integrated gate-commutated thyristors (IGCT), bipolar junction transistors (BJT) with anti-parallel diodes, insulated-gate bipolar transistors (IGBT), field-effect transistors (FETs) like enhancement-mode and/or depletion-mode metal-oxide-semiconductor (MOS-FET), Gallium Nitride (GaN-FET), Silicon Carbide metal-oxide-semiconductor (SiC MOSFET), V-groove metal-oxide semiconductor (VMOS), junction-gate field-effect transistors (JFET) or high electron-mobility transistors (HEMT), based on IV-IV or III-V semiconductor materials like silicon (Si), siliconcarbide (SiC), silicon-germanium (SiGe), gallium-nitride (GaN), gallium-arsenid (GaAs), gallium-oxide (GaO).

For the sake of brevity and without loss of generality, the following description utilizes a silicon-MOSFET as an example of a semiconductor switching device and refers to the control terminal of the switching device as the gate of the device for brevity. However, the methods and circuits described herein are applicable to other controllable semiconductor switching devices with gate capacitance.

The semiconductor device (e.g. transistor 12) controlled in method 100 may be characterized as being in one of three states for any switching operation: a starting state 103, a transition state 105 (occasionally referred to as “transition” herein), and an ending state 107. Starting state 103 may be a steady state. Starting state 103 may be a steady state ON state (e.g. where the transistor being controlled is conducting in a steady state) or a steady state OFF state (e.g. where the transistor is being controlled is non-conducting in a steady state). Ending state 107 may also be a steady state. Ending state 107 may be a steady state ON state or a steady state OFF state. For example, in a turn-ON operation, starting state 103 is in a steady state OFF state (e.g. the transistor being controlled is non-conducting) and ending state 107 is in a steady state ON state (e.g. the transistor being controlled is conducting). Conversely, in a turn-OFF operation, starting state 103 is in a steady state ON state (e.g. the transistor being controlled is conducting) and ending state 107 is in a steady state OFF state (e.g. the transistor being controlled is non-conducting). Transition state 105 may be defined to be the state of the semiconductor transistor between starting state 103 and ending state 107. The switching of the transistor between starting steady state 103 and ending steady state 107 may be referred to as commutation.

By way of non-limiting example, a semiconductor transistor in an “ON steady state” (sometimes referred to herein as an ON state for brevity), in the context of this disclosure, may mean meeting one or more of the following conditions for a period of time that is at least as long as the period of the resonant tank defined by the parasitic inductance of the gate terminal and the gate capacitance (e.g. by Lₚₐᵣ and Cᵢₛₛ):
a value of gate-source voltage v_{GS} of the semiconductor transistor has converged to within ±5% or ±10% or ±15% of a desired gate-source voltage v_{GS} ON value v_{GS_on}, where the ON value v_{GS_on} is a configurable operational parameter which is greater than Vₜₕ and may be specific to any given circuit and/or transistor;
a value of gate current i_{G} into the gate of the transistor has converged to near zero (e.g. within ±5% or ±10% or ±15% of the leakage gate current of transistor 12); and
a value of the current i_{D} through the transistor has converged to within ±5% or ±10% or ±15% of a desired operational value of drain current i_{D_on}, where the desired operational value of drain current i_{D_on} is a configurable operational parameter which may be specific to any given circuit and/or transistor.

By way of non-limiting example, a semiconductor transistor in an “OFF steady state” (sometimes referred to herein as an OFF state for brevity), in the context of this disclosure, may mean meeting one or more of the following conditions for a period of time that is at least as long as the period of the resonant tank defined by the parasitic inductance of the gate terminal and the gate capacitance (e.g. by Lₚₐᵣ and Cᵢₛₛ):
a value of gate-source voltage v_{GS} of the semiconductor transistor has converged to within ±5% or ±10% or ±15% of a desired gate-source voltage v_{GS} OFF value v_{GS_off}, where the OFF value v_{GS_off} is a configurable operational parameter which is less than Vₜₕ and may be specific to any given circuit and/or transistor;
a value of gate current i_{G} has converged to near zero (e.g. within ±5% or ±10% or ±15% of the leakage gate current of transistor 12); and
a value of the current i_{D} through the transistor has converged to approximately zero (e.g. within ±5% or ±10% or ±15% of the drain-to-source leakage current of transistor 12).

Method 100 begins with the transistor 12 in a starting state 103. Method 100 comprises performing step 102 of providing a first gate-driving voltage pulse (e.g. first pulse 210 of a turn-ON operation or first pulse 220 of a turn-OFF operation) having a first effective amplitude. The first gate-driving voltage pulse may be provided when the transistor is in a starting state 103. The first effective amplitude of the first voltage pulse may comprise any suitable amplitude and, in some embodiments, may be sufficient to cause v_{GS} to cross the threshold voltage Vₜₕ of MOSFET 12. In a non-limiting example embodiment of a turn-ON operation, the first effective amplitude of the first gate-driving voltage pulse may be from v_{off} to vₒₙ (see rising edge 214 of first turn-ON pulse 210 of plot 200A′ of FIG. 2B), where v ff is less than Vₜₕ (e.g. 0v) and vₒₙ is greater than Vₜₕ. In a non-limiting example embodiment of a turn-OFF operation, the first gate-driving voltage pulse may be a negative voltage pulse with an effective amplitude from vₒₙ to v_{off} (see falling edge 224 of first turn-OFF pulse 220 of plot 200A′ of FIG. 2B), where, in some embodiments, v_{off} is less than Vₜₕ (e.g. 0v) and vₒₙ is greater than Vₜₕ. The gate-driving signal V_{DR} may be described as being a gate-discharging signal during a turn-OFF operation. The first gate-driving voltage pulse may have a duration (e.g. t_{A} in the FIG. 2B embodiment) after which the gate-driving signal returns to some intermediate value which may be the value that it had in starting state 103. For example, in the non-limiting example embodiment of a turn-ON operation shown in FIG. 2B, first turn-ON pulse 210 may return from vₒₙ to v_{off} (see falling edge 216 of first turn-ON pulse 210 of plot 200A′ of FIG. 2B)—i.e. v ff is the intermediate value between pulses. In the non-limiting example embodiment of a turn-OFF operation shown in FIG. 2B, first turn-OFF pulse 220 may return from v_{off} to von (see rising edge 226 of first turn-OFF pulse 220 of plot 200A′ of FIG. 2B)—i.e. vₒₙ is the intermediate value between pulses.

The first gate-driving voltage pulse may have a duration (e.g. t_{A} in the FIG. 2B embodiment) that is less than the time required for the transistor (e.g. MOSFET 12) to transition from starting state 103 to ending state 107, so that the transistor is in transition state 105 at the end of the first pulse when the gate-driving signal returns to the intermediate value (e.g. the value that it had in starting state 103). As discussed elsewhere herein, the durations of the first gate driving pulses 210, 220 in the exemplary FIG. 2B turn-ON operation and in the exemplary FIG. 2B turn-OFF operation are shown as being equal (e.g. t_{A} in the FIG. 2B embodiment), but this is not necessary and the durations of the first gate-driving pulses can be different as between turn-ON and turn-OFF operations. As explained in more detail below, in some embodiments, the first voltage pulse comprises a pulse width modulated (PWM) signal and the first “effective” amplitude of the first gate-driving pulse is based on (e.g. a product of) a duty cycle and amplitude of the PWM signal.

Returning to FIG. 3, method 100 then proceeds with step 104 of providing a second gate-driving voltage pulse (e.g. second pulse 212 of a turn-ON operation or second pulse 222 of a turn-OFF operation in the illustrated embodiment of FIG. 2B) having a second effective amplitude. The second gate-driving voltage pulse is applied (i.e. starts) during transition 105 of the semiconductor transistor between starting state 103 and ending state 107. In the illustrated embodiment, there is a delay (e.g. t_{B} in the FIG. 2B embodiment) between the end of the first gate-driving voltage pulse and the start of the second gate-driving voltage pulse. During this delay, the gate-driving voltage may have an intermediate value. The intermediate value may be on the same side of Vₜₕ as the value in starting state 103. For example, if the gate-driving voltage was below Vₜₕ at starting state 103, then the intermediate value of the gate-driving voltage may return below Vₜₕ or, if the gate-driving voltage was above Vₜₕ at starting state 103, then the intermediate value of the gate-driving voltage may return to a value above Vₜₕ. In the illustrated FIG. 2B embodiment, the intermediate value of the gate-driving voltage between the first and second pulses (e.g. during the time t_{B} in the FIG. 2B embodiment) is the same value that it had in starting state 103. For example, in the non-limiting example embodiment of a turn-ON operation shown in FIG. 2B, during the delay between falling edge 216 of first turn-ON pulse 210 and rising edge 218 of second turn-ON pulse 212, the gate drive signal may have the value v_{off}. In the example non-limiting example embodiment of a turn-OFF operation shown in FIG. 2B, during the delay between rising edge 226 of first turn-OFF pulse 220 and falling edge 228 of second turn-OFF pulse 222, the gate drive signal may have the value von. The temporal spacing between the end of the first pulse and the start of the second pulse (e.g. t_{B} in the FIG. 2B embodiment) may be less than the time required for the transistor to transition from transition state 105 back to starting state 103, so that the second pulse is applied (i.e. starts) when the transistor is still in transition state 105. As discussed elsewhere herein, the durations of the delays between the first and second gate driving pulses 210, 212 in the exemplary FIG. 2B turn-ON operation and between the first and second gate driving pulses 220, 222 in the exemplary FIG. 2B turn-OFF operation are shown as being equal (e.g. t_{B} in the FIG. 2B embodiment), but this is not necessary and the durations of the delays between first and second gate-driving pulses can be different as between turn-ON and turn-OFF operations.

The second effective amplitude of the second voltage pulse may comprise any suitable amplitude and, in some embodiments, may be sufficient to cause V_{GS} to cross the threshold voltage Vₜₕ of MOSFET 12. In a non-limiting example embodiment of a turn-ON operation, the second effective amplitude of the second gate-driving voltage pulse may be from v_{off} to vₒₙ(see rising edge 218 of second turn-ON pulse 212 of plot 200A′ of FIG. 2B), where v_{off} is less than Vₜₕ (e.g. 0v) and vₒₙ is greater than Vₜₕ. In a non-limiting example embodiment of a turn-OFF operation, the second gate-driving voltage pulse may be a negative voltage pulse with a second effective amplitude from vₒₙ to v_{off} (see falling edge 228 of second turn-OFF pulse 222 of plot 200A′ of FIG. 2B), where v_{off} is less than Vₜₕ (e.g. 0v) and vₒₙ is greater than Vₜₕ. The gate-driving signal V_{DR} may be described as being a gate-discharging signal during a turn-OFF operation.

The second gate-driving voltage pulse may have a duration that is greater than the time required for the transistor (e.g. MOSFET 12) to transition from transition state 105 to ending state 107, so that the transistor reaches ending state 107 during the second pulse. As explained in more detail below, in some embodiments, the second voltage pulse comprises a pulse width modulated (PWM) signal and the second “effective” amplitude is based on (e.g. a product of) a duty cycle and amplitude of the PWM signal.

In the example embodiment of FIG. 2B, during the turn-ON operation which involves first pulse 210 and second pulse 212, it can be observed that starting state 103 of MOSFET 12 is steady state OFF (non-conducting) state prior to the application of first pulse 210, that second pulse 212 starts when MOSFET 12 is in a transition state 105 and that ending state 107 of MOSFET 12 is a steady state ON (conducting) state which is reached during the second voltage pulse 212. During the turn-OFF operation which involves first pulse 220 and second pulse 222, it can be observed that starting state 103 of MOSFET 12 is a steady state ON (conducting) state prior to the application of first pulse 220, that second pulse 222 starts when MOSFET 12 is in a transition state 105 and that ending state 107 of MOSFET 12 is a steady state OFF (non-conducting) which is reached during the second voltage pulse 212.

In some embodiments, additional gate-driving pulses may be applied when the transistor is in transition state 105 (e.g. between the first voltage pulse which is applied when the transistor is in starting state 103 and the second voltage pulse which is applied when the transistor is in transition state 105 but lasts until the transistor is in the ending state 107 as described above). Such additional gate-driving pulses may have the same or different pulse parameters (e.g. pulse amplitude, effective pulse amplitude, pulse voltage levels, pulse duration, temporal pulse separation, pulse frequency, pulse duty cycle, charge time and/or the like) than each other and/or than the first and second pulses of the FIG. 2B embodiment. Any of these gate-driving pulse parameters may be tunable or actively controlled or controllable. Examples, of tuning and controlling gate-driving pulse parameters are described below.

In the embodiments described herein the gate-driving voltage source is connected directly to the gate of the device being controlled. In some embodiments, it may be desirable to provide one or more additional components (e.g. inductors, resistors and/or the like) in series between the gate-driving voltage source and the gate to provide design flexibility. In some embodiments, it may be desirable to provide one or more additional components (e.g. capacitors, diodes and/or the like) in parallel between the gate and the source to provide design flexibility.

### Example Embodiments

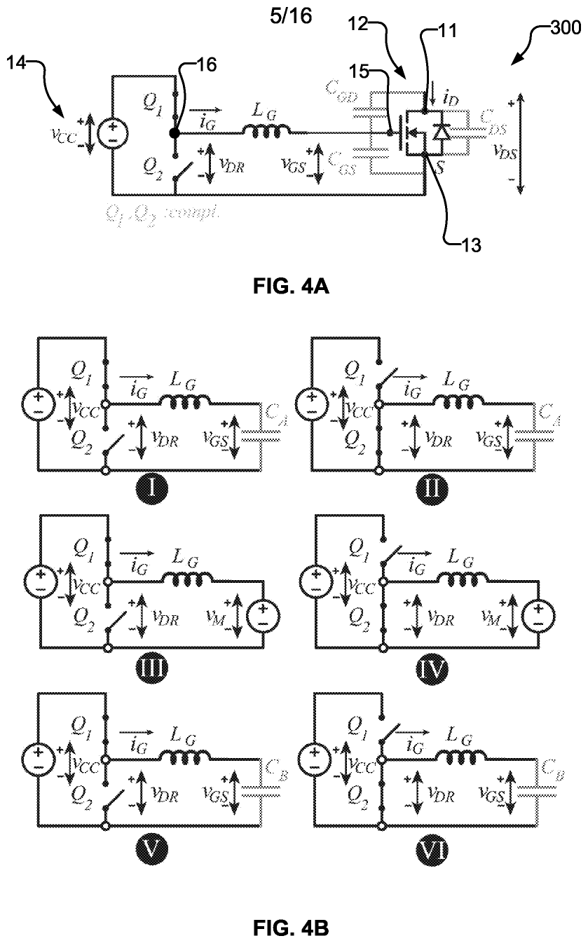

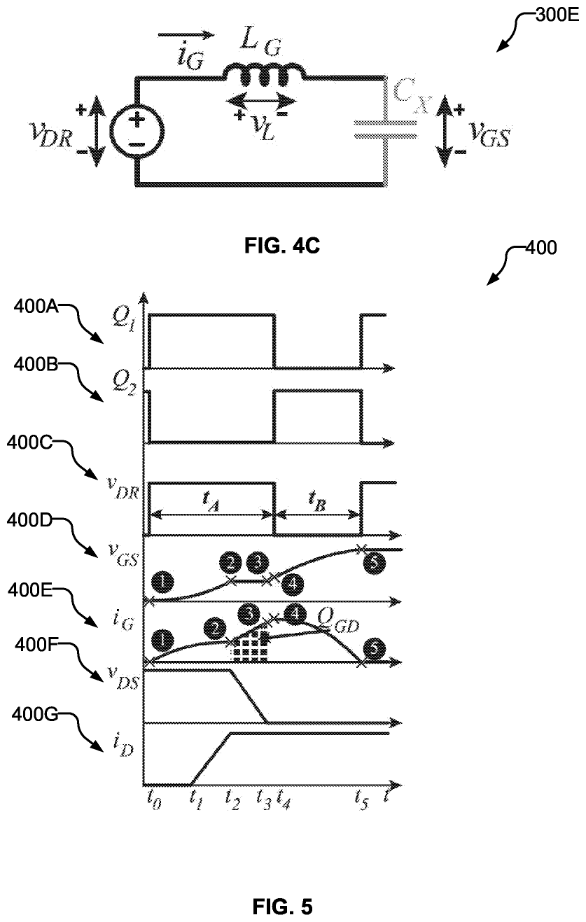

FIG. 4A is a schematic circuit diagram of an enhancement mode metal oxide semiconductor field-effect transistor (MOSFET) 12 and a corresponding gate-driving circuit 300 suitable for use with the multi-pulse gate-driving methodology of FIGS. 2A and 3 according to a particular embodiment of the invention. MOSFET 12 of the FIG. 4A embodiment may be substantially similar to MOSFET 12 described elsewhere herein and comprises a drain terminal 11, a source terminal 13, a gate terminal 15 and an internal body diode 17. Gate-driving circuit 300 is supplied by a gate-control voltage source 14 which may be substantially similar to gate-control voltage source 14 described herein and, in the case of the illustrated embodiment, comprise a half-bridge topology comprising switches Q₁ and Q₂. FIG. 4A and circuit 300 are similar to FIG. 2A and circuit 110, except that: FIG. 4A and circuit 300 explicitly show the gate-to-source capacitance C_{GS}, the gate-to-drain capacitance C_{GD} and the drain-to-source capacitance C_{DS} which are associated with the physical and electrical properties of MOSFET 12; and, in circuit 300, the parasitic inductance L_{Par} associated with the gate drive is replaced with and inductance L_{G} to indicate that this inductance LG may comprise a combination of parasitic inductance and added inductance such that to some degree the inductance LG is actually a controllable parameter of the FIG. 4A circuit 300. FIG. 4B shows a plurality of six operational modes or states (identified by Roman numerals I, II, III, IV, V and VI) of the FIG. 4A gate-driving circuit 300. FIG. 4C shows a simplified equivalent gate-driving circuit 300E of gate-driving circuit 300 of FIG. 4A.

Each of the plurality of modes I-VI of the FIG. 4B gate-driving circuit 300 can be represented with FIG. 4C equivalent circuit 300E with gate-driving voltage v_{DR} and equivalent capacitance C_{X} for each state described by:

$$\{ \begin{matrix}0 , & II , IV , V I ; \\ {V}_{CC} , & I , III , V ;\end{matrix} \qquad ( 1 )$$

$${C}_{X} = \{ \begin{matrix}{C}_{A} = {C}_{iss} , & I , II ; \\ ∞ , & III , IV ; \\ {C}_{B} = \frac{{Q}_{T}}{{V}_{CC}} , & V , VI ;\end{matrix}$$

where: Q_{T} is the total gate charge of MOSFET 12 (typically a known parameter of MOSFET 12) and V_{CC} is the driver supply voltage (described as V_{ON} in the context of FIG. 2B). For equivalent circuit 300E:

v_{L}+v_{GS}=v_{DR} (2)

which can be extended through differential equations for v_{L} and V_{GS} to:

$${L}_{G} \frac{{di}_{G}}{dt} + \frac{1}{{C}_{X}} \int {i}_{G} dt = {v}_{DR} \qquad ( 3 )$$

To obtain generality and simple representation of the dynamic behavior in the state plane, the time (t), voltages (vₓ), currents (iₓ), and charges (qₓ) may be normalized according to:

$${t}_{xn} , = \frac{{t}_{x}}{{T}_{0 x}} ; {v}_{xn} = \frac{{v}_{x}}{{v}_{norm}} ; {i}_{xn} = \frac{{i}_{x}}{{i}_{norm}} ; {q}_{xn} = \frac{{q}_{x}}{{q}_{norm}} \qquad ( 4 )$$

where the subscript n indicates that the variables are normalized and the subscript x is a placeholder for a corresponding variable. For example, V_{GSn} is the normalized gate-source voltage. The base quantities of the circuit 300E resonant circuit (also referred to as a resonant tank) are described by:

$${T}_{0 X} = 2 π \sqrt{{L}_{G} {C}_{X}} ; {Z}_{0 X} = \sqrt{\frac{{L}_{G}}{{C}_{X}}} ; {ω}_{X} = \frac{1}{\sqrt{{L}_{G} {C}_{X}}} \qquad ( 5 )$$

where T_{0X} is the period, Z_{0X} is the characteristic impedance and ω_{X} is the angular speed of the resonant tank. The normalizing voltage, current and charge may be:

$${v}_{n o r m} = {V}_{cc} ; {i}_{n o r {m}_{x}} = \frac{{v}_{n o r m}}{{Z}_{0 X}} ; {q}_{n o r m} = {v}_{n o r m} {C}_{X} \qquad ( 6 )$$

With this normalization and the relationships between qₙ, i_{Gn} and v_{GSn} via

$${i}_{{G}_{n}} = \frac{d {q}_{n}}{d {t}_{n}} ; {v}_{G {S}_{n}} = \frac{{q}_{n}}{{C}_{X}} \qquad ( 7 )$$

equation (3) may be rewritten as

$$\frac{{d}^{2} {q}_{n} ( {t}_{n} )}{d {t}_{n}^{2}} + \frac{{q}_{n} ( {t}_{n} )}{{L}_{G} {C}_{X}} = \frac{{v}_{D {R}_{n}}}{{L}_{G}} \qquad ( 8 )$$

Solving the general differential equation (8) results in the particular time-domain equations for v_{GSn} via (7) as

v_{GS}_{ₙ}(tₙ)=AZ₀ₓ sin(ω_{X}tₙ)+B COS(ω_{X}tₙ)+v_{DR}_{ₙ} (9)

and for i_{G}_{ₙ} via (7) as

$${i}_{{G}_{n}} ( {t}_{n} ) = A cos ( {ω}_{X} {t}_{n} ) - \frac{B}{{Z}_{0 X}} sin ( {ω}_{X} {t}_{n} ) \qquad ( 10 )$$

with A=i_{G}_{ₙ}(0), B=v_{GS}_{ₙ}(0)−v_{DR}_{ₙ}, where v_{GS}_{ₙ}(0) is the initial voltage for v_{GS}_{ₙ} and i_{G}_{ₙ}(0) is the initial current for i_{G}_{ₙ}. Combining equations (9) and (10) to eliminate the time variable results in a circular state plane described by

i_{Gn}²+(v_{GS}_{ₙ}−v_{DR}_{ₙ})²=i_{Gn(0)}²+(v_{GS}_{ₙ₍₀₎}−v_{DR}ⁿ)² (11)

The transient behavior in the six states I-VI of FIG. 4B can then be described in the time domain by equations (9) and (10) and in state space by equation (11).

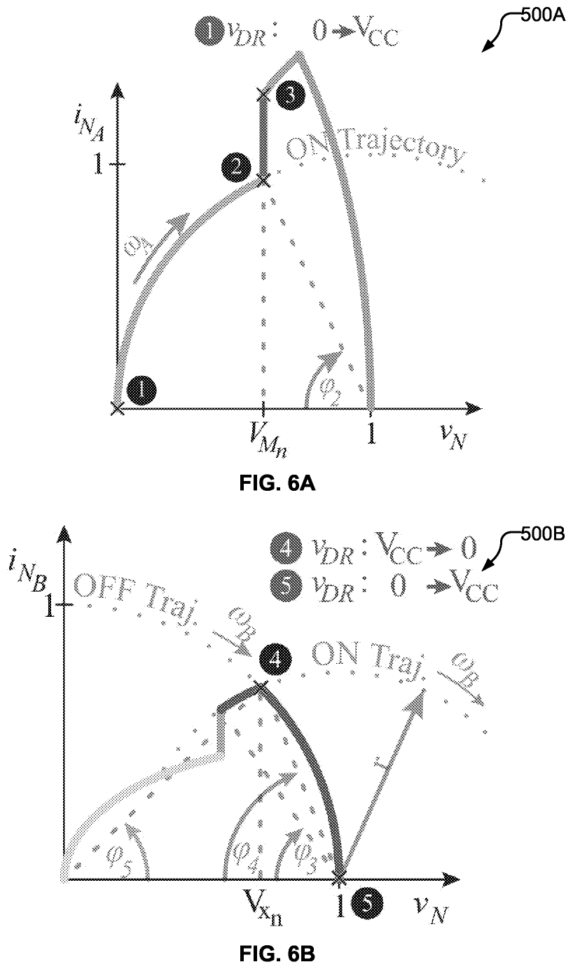

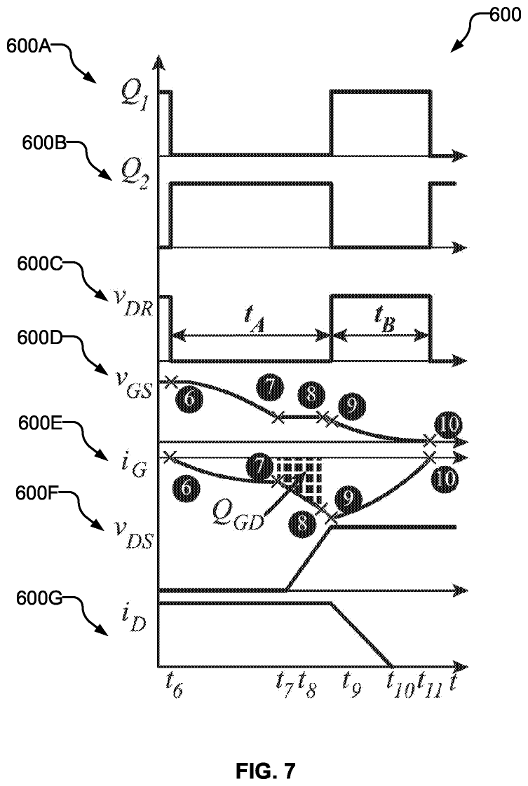

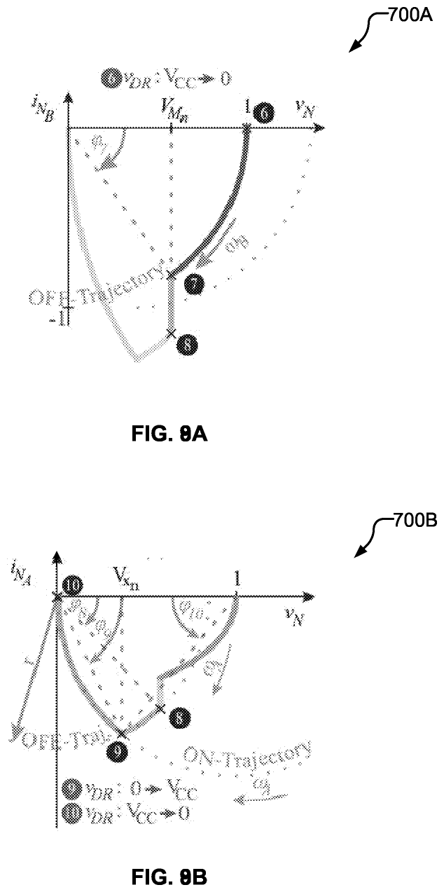

FIG. 5 shows a plurality of plots 400A to 400G of various circuit parameters of gate-driving circuit 300 during the application of a multi-pulse turn-ON operation according to a particular embodiment. FIG. 6A shows a state plane plot 500A normalized to a current i_{N}_{_{A}} (according to capacitance C_{A}) during time period t_{A} as defined in equation (12) and shown in FIG. 5. FIG. 6B shows a state plane plot 500B normalized to a current i_{N}_{_{B}} (according to capacitance C_{B}) during time period t_{B} as defined in equation (12) and shown in FIG. 5. FIG. 7 shows a plurality of plots 600A to 600G of various circuit parameters of gate-driving circuit 300 during the application of a multi-pulse turn-OFF operation according to a particular embodiment. FIG. 8A shows a state plane plot 700A normalized to a current i_{N}_{_{A}} during time period t_{A} as defined in equation (12) and shown in FIG. 7. FIG. 8B shows a state plane plot 700B normalized to a current i_{N}_{_{B}} during time period t_{B} as defined in equation (12) and shown in FIG. 7.

The following section of this disclosure describes the timing of the multi-pulse driving sequence 4000 (FIG. 5) of the turn-ON operation with the aid of the waveforms shown in FIG. 5. In the particular case of the illustrated embodiment, the parameters t_{A}, t_{B} are selected to be the same in the turn-ON operation driving sequence 4000 and in the turn-OFF operation 6000 (FIG. 7), although this symmetry of the turn-ON and turn-OFF operations is generally not necessary. With this symmetry and having regard to FIGS. 5 and 7, the parameters t_{A}, t_{B} may be described according to:

t_{A}=t₀₋₂+t₂₋₃+t₃₋₄=t₆₋₇+t₇₋₈+t₈₋₉

t_{B}=t₄₋₅=t₉₋₁₁ (12)

The turn-ON operation is described in detail herein with the understanding that the symmetrical (in the case of the illustrated embodiment) turn-OFF operation is analogous.

Interval t₀₋₂

Prior to this interval, V_{DR}=0 is applied to keep MOSFET 12 OFF. The interval t₀₋₂ begins at t₀ with v_{GS}_{ₙ}(0)=0 and i_{G}_{ₙ}(0)=0 and represents state I as identified in equation (1) and FIG. 4B. This interval ends at t₂ where v_{GS} meets the so-called Miller voltage V_{M} which is described by

$${V}_{M} = {V}_{t h} + \frac{{i}_{D}}{{g}_{m}} \qquad ( 13 )$$

$$at$$

$${t}_{0 - 2} = \frac{a cos ( 1 - {V}_{{M}_{n}} )}{{ω}_{A}} \qquad ( 14 )$$

where ω_{A} is the angular speed of the resonant tank with Cₓ=C_{A}, Vₜₕ is the threshold voltage and gₘ is the transconductance of MOSFET 12.
Interval t₂₋₃

This interval corresponds to state III as identified in equation (1) and FIG. 4B at begins at t₂ with v_{GS}_{ₙ}(0)=V_{M}_{ₙ} and i_{G}_{ₙ}(0)=i_{G}_{ₙ}(t₂). The initial current in this interval is given by

i_{G}_{ₙ}(t₂)=iₙₒᵣₘ_{_{A}} sin(ω_{A}t₀₋₂) (15)

where iₙₒᵣₘ_{_{A}} is the normalized current considering the resonant tank with Cₓ=C_{A}. This interval ends at t₃ when the gate-drain charge (Q_{GD}) of C_{GD} is delivered by i_{G} via

$${Q}_{G D} = {\int }_{{t}_{2}}^{{t}_{3}} {i}_{G} d t = {i}_{G} ( {t}_{2} ) {t}_{2 - 3} + 0.5 {t}_{2 - 3} Δ {i}_{23} \qquad ( 16 )$$

$$where$$

$$Δ {i}_{23} \approx {t}_{2 - 3} \frac{{V}_{D R} - {V}_{M}}{{L}_{G}} \qquad ( 17 )$$

Consequently, equation (16) can be rewritten, with equation (17) and the shorthand

$$M = \frac{( {v}_{D R} - {V}_{m} )}{{L}_{G}} ,$$

as

$${Q}_{GD} \approx {I}_{g} ( {t}_{2} ) {t}_{2 - 3} + 0. 5 {t}_{2 - 3}^{2} M \qquad ( 18 )$$

$$resulting in$$

$${t}_{2 - 3} \approx - \frac{{i}_{G} ( {t}_{2} )}{M} + \sqrt{{( \frac{{i}_{G} ( {t}_{2} )}{M} )}^{2} + \frac{2 {Q}_{G D}}{M}} \qquad ( 19 )$$

Interval t₃₋₄

This interval corresponds to state V described in equation (1) and FIG. 4B and starts at t₃ with v_{GS}_{ₙ}(0)=V_{M}_{ₙ} and i_{G}_{ₙ}(0)=i_{G}_{ₙ}(t₃). The initial current in this interval is determined by

$${i}_{{G}_{n}} ( {t}_{3} ) = {i}_{{G}_{n}} ( {t}_{2} ) + \frac{Δ {i}_{23}}{{i}_{{norm}_{B}}} \qquad ( 20 )$$

This interval ends at t₄, where the ON-trajectory (shown in grey-scale in FIGS. 6A, 6B) intersects with the OFF-trajectory (shown in grey-scale in FIG. 6B). The OFF-trajectory can be described via equation (11) as

$${i}_{G n}^{2} + {v}_{G S n}^{2} = 1 \qquad ( 21 )$$

whereas the ON-trajectory can be described by equation (11) as

$${i}_{G n}^{2} + {( {v}_{G {S}_{n}} - {v}_{D {R}_{n}} )}^{2} = {i}_{G n ( {t}_{3} )}^{2} + {( {V}_{{M}_{n}} - {v}_{D {R}_{n}} )}^{2} \qquad ( 22 )$$

The normalized intersecting voltage (Vₓ_{ₙ}) can be found by combining equations (21) and (22) to

$${V}_{{x}_{n}} = 1 - 0.5 {r}^{2} \qquad ( 23 )$$

$$where$$

$$r = \sqrt{{i}_{G n ( {t}_{3} )}^{2} + {( {V}_{{M}_{n}} - {v}_{D {R}_{n}} )}^{2}} \qquad ( 24 )$$

With Vₓ_{ₙ} determined, the length of this interval can be defined via the angular difference of the voltage vectors v_{GS}_{ₙ}(t₃) and v_{GS}_{ₙ}(t₄) (see FIG. 6B) through

$${t}_{3 - 4} = \frac{{ϕ}_{4} - {ϕ}_{3}}{{ω}_{B}} = \frac{a cos ( \frac{1 - {V}_{{M}_{n}}}{r} ) - a cos ( \frac{1 - {V}_{{x}_{n}}}{r} )}{{ω}_{B}} \qquad ( 25 )$$

where ω_{B} is the angular speed of the resonant tank with Cₓ=C_{B}.
Interval t₄₋₅

This interval corresponds to state VI described in equation (1) and FIG. 4B and starts at t₄ with v_{GS}_{ₙ}(0)=Vₓ_{ₙ} and i_{G}_{ₙ}(0)=i_{G}_{ₙ}(t₄). The initial current in this interval is determined by

i_{G}_{ₙ}(t₄)=i_{G}_{ₙ}(t₃)+iₙₒᵣₘ_{_{B}} sin(t₃₋₄ω_{B}) (26)

This interval ends at t₅, where the target points for v_{GS} an i_{G}_{ₙ} are reached. The time for this is determined by

$${t}_{4 - 5} = \frac{a cos ( {V}_{{x}_{n}} )}{{ω}_{B}} \qquad ( 27 )$$

At the end of this interval, v_{DR}=v_{CC} (a second pulse) is applied to keep MOSFET 12 ON, which concludes the multi-pulse gate-drive sequence which (when compared to prior art techniques which use a gate resistance R_{G}) provides swift commutation times, while maintaining low voltage stress and reduced oscillations in the gate circuitry for the turn-ON operation. As described above, the turn-OFF operation is analogous to the turn-ON operation and, consequently, the detailed description of the turn-OFF operation is omitted for breviy.

The above-derived equations may be used to determine the parameters t_{A} and t_{B} for the turn-ON drive sequence 4000 (FIG. 5) and the turn-OFF drive sequence 6000 (FIG. 7) according to the particular case of the illustrated embodiment. For practicality, these equations (e.g. equations (14), (19) and (25) and equation (27)) can be simplified to provide the following approximations:

$${t}_{A} \approx \sqrt{{L}_{G} {C}_{i s s}} ( a cos ( 1 - {V}_{{M}_{n}} ) - \frac{\sqrt{2 {V}_{{M}_{n}} - {V}_{{M}_{n}}^{2}}}{1 - {V}_{{M}_{n}}} ) + \sqrt{\frac{2 {L}_{G} {Q}_{G D}}{{V}_{C C} - {V}_{M}} - \frac{{L}_{G} {C}_{i s s} {V}_{C C}^{2} ( {V}_{{M}_{n}}^{2} - 2 {V}_{{M}_{n}} )}{{( {V}_{C C} - {V}_{M} )}^{2}}} \qquad ( 28 )$$

$$and$$

$${t}_{B} \approx \sqrt{{L}_{G} \frac{{Q}_{T}}{{V}_{CC}}} a cos ( {V}_{{M}_{n}} ) \qquad ( 29 )$$

Equations (28), (29) together with equation (13) can be used to determine approximate values for the parameters t_{A} and t_{B} based on quantities/parameters (e.g. Cᵢₛₛ, Q_{GD}, Q_{T}, vₜₕ, gₘ) that are typically present in the datasheet of a MOSFET power switching transistor (e.g. MOSFET 12) together with quantities/parameters (e.g. the operating drain current i_{D}, L_{G}, V_{cc}) of the circuit in which MOSFET 12 is being used. Equations (28) and (29) represent approximations as described above. In some embodiments, different approximations or even equations (14), (19) and (25) and equation (27) may be used to determine multi-pulse parameters t_{A} and t_{B}.

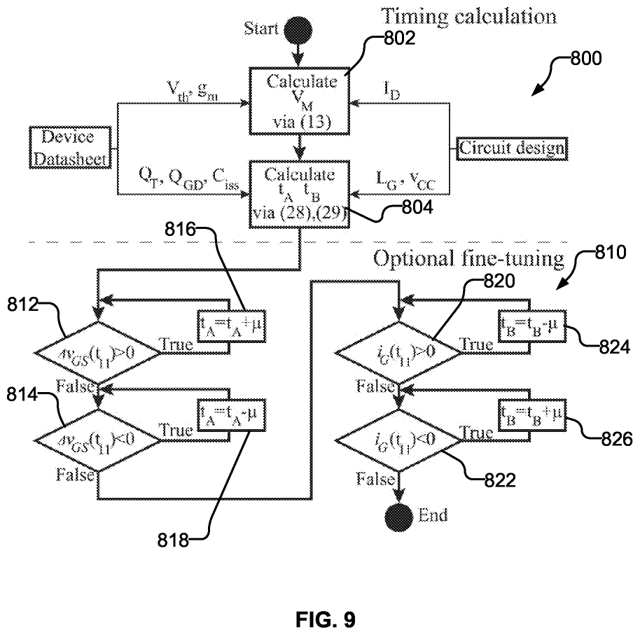

FIG. 9 is a schematic illustration of a method 800 for determining the parameters t_{A} and t_{B} according to particular embodiment, where block 802 involves determining the parameter V_{M} based on datasheet parameters vₜₕ, gₘ and circuit parameter I_{D} and block 804 involve calculating t_{A} and t_{B} based on the block 802 value for V_{M}, the datasheet parameters Cᵢₛₛ, Q_{GD}, Q_{T} and the circuit parameters L_{G}, V_{cc}. In some embodiments, block 802 may involve the use of equation (13) described above and block 804 may involve the use of simplified equations (28) and (29) described above.

FIG. 9 also shows an optional fine turning adjustment method 810 using an additional incremental time-adjustment parameter μ. The time-adjustment parameter μ may be determined on the basis of the quantities v_{GS} and i_{G} at t₁₁ during the turn-OFF operation (see FIG. 7). In particular, if the quantity Δv_{gs}(t₁₁)>0 (as determined at block 812) then parameter t_{A} can be incremented by time-adjustment μ at block 816; if the quantity Δv_{gs}(t₁₁)<0 (as determined at block 814) then parameter t_{A} can be decreased by time-adjustment y at block 818; if the quantity i_{G}(t₁₁)>0 (as determined at block 820) then parameter t_{B} can be decreased by time-adjustment μ at block 824 and/or i_{G} (t₁₁)<0 (as determined at block 822) then parameter t_{B} can be increased by time-adjustment μ at block 826. In some embodiments, the value of time-adjustment parameter μ may be different for adjusting t_{A} in blocks 816, 818 than for adjusting t_{B} in blocks 824, 826.

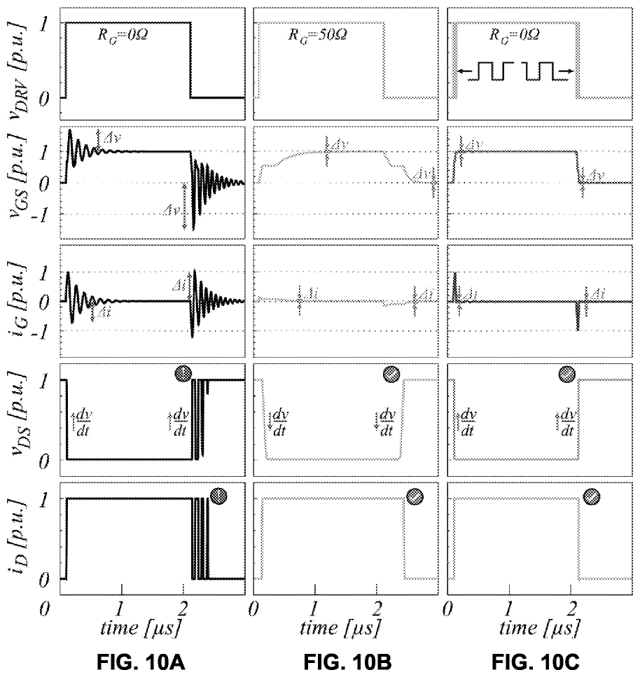

FIGS. 10A, 10B, 10C (collectively, FIG. 10) illustrate a comparison of the traditional approach (using single step function gate-drive signal v_{DR} and a gate resistance R_{G}) for the underdamped condition with R_{G}=0Ω and L_{G}=L_{Par}=100 nH (FIG. 10A), the overdamped condition with R_{G}=50Ω and L_{G}=L_{Par}=100 nH (FIG. 10B) applied to the FIG. 1A circuit 10 and the multi-pulse approach shown in plots 4000, 6000 of FIGS. 5, 7 applied to the circuit of FIG. 4A 300 with R_{G}=0Ω and L_{G}=100 nH. FIG. 10A shows that the traditional underdamped response results in swift commutation times but suffers from excessive voltage stress and large oscillations, which lead to multiple false turn-ON failures in the turn-OFF operation as seen in the plots of v_{DS} and i_{D}. FIG. 10B shows that the traditional overdamped response results in slow transients with reduced voltage stress and oscillations, mitigating false turn-ON failures. However, this overdamped approach suffers from significantly reduced slew-rates with the consequential penalty in efficiency (switching power loss). In contrast to the traditional approach, the proposed multi-pulse gate-drive signal shown in FIG. 10C achieves swift commutation times while maintaining low voltage stress and oscillations, which effectively mitigates false turn-ON failures.

In various experiments, the inventors have been able to demonstrate 5X and 18× reduction in oscillation amplitude, while delivering the same peak output current (1.2A) with respect to the conventional approach for v_{GS} and i_{G} respectively, which permits the multi-pulse approach described herein to operate the transistor with relatively fast slew rates while mitigating false turn-ON failures. Further, using the commonly used double pulse test, the inventors have demonstrated switching loss reductions of up to 22% at v_{DD}=400V using the multi-pulse gate driving technique described herein relative to the traditional (single step) gate driving technique incorporate a gate resistance R_{G}.

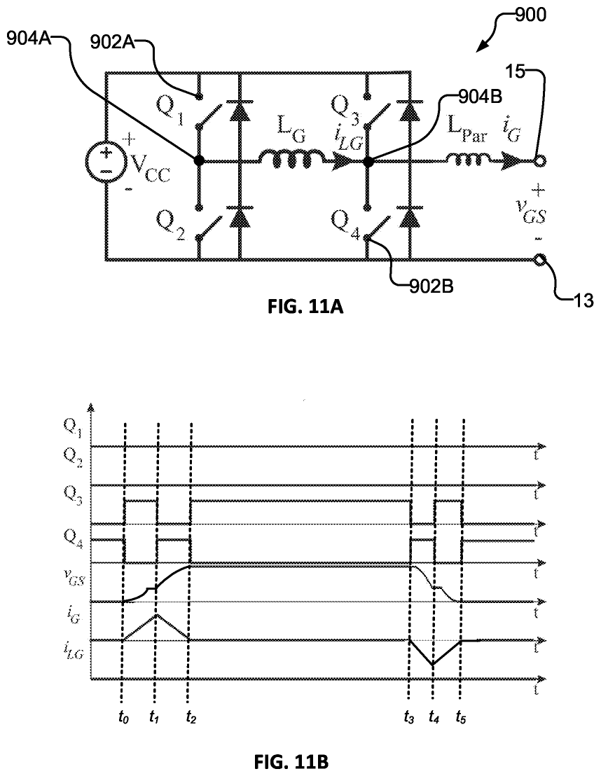

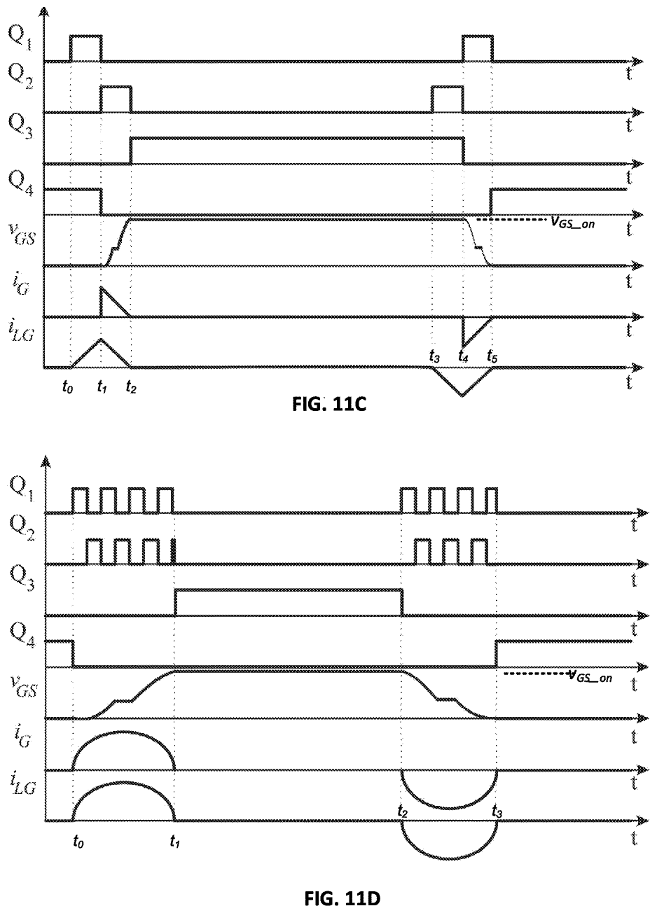

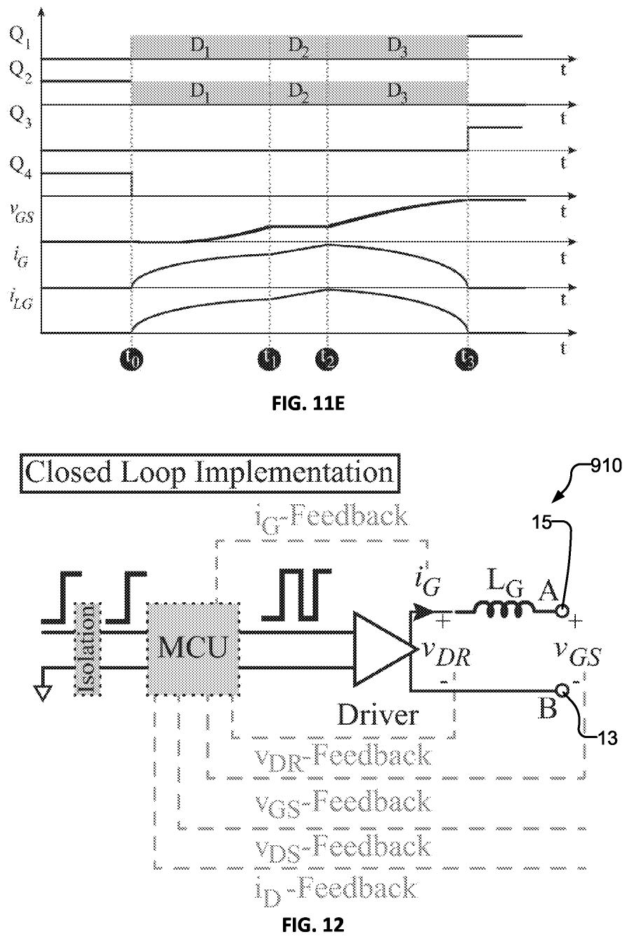

FIG. 11A is a schematic circuit diagram of full full-bridge circuit 900 which can be used to provide a multi-pulse gate-driving methodology according to a particular embodiment of the invention. Full-bridge circuit 900 comprises a pair of branches 902A, 902B4 connected between the terminals of voltage source V_{cc}. First branch 902A comprises switches Q₁, Q₂ and a first full-bridge switched terminal 904A therebetween; second branch 902A comprises switches Q₃, Q₄ and a second full-bridge switched terminal 904B therebetween. Inductor LG is connected between full-bridge switched terminals 904A, 904B. In the illustrated embodiment, full-bridge switched terminal 904B is connected to directly to gate node 15 by an electrically conductive (e.g. metal) connection—e.g. any resistance between half-bridge terminal 16 and gate node 15 is the inherent internal resistance of the electrically conductive connection (including, possibly, any internal driver and/or MOSFET connections (e.g. of the full-bridge)) and inductance Lₚₐᵣ is the inherent or parasitic inductance of this conductive connection (including, possibly, any internal driver and/or MOSFET connections (e.g. of the full-bridge)). Full-bridge circuit 900 can operate in a number of operating modes. The FET being controlled is omitted from FIG. 11A, but its gate node 15 and source node 13 are shown as well as the gate current i_{G} and gate-source voltage v_{GS}. FIG. 11B is a schematic illustration of a number of circuit parameters of the FIG. 11A full-bridge circuit 900 when operating in an operating mode A which is equivalent to the half-bridge configuration described elsewhere herein, wherein switches Q₃ and Q₄ of circuit 900 are analogous to switches Q₁ and Q₂ of circuits 110 (FIG. 2A) and 300 (FIG. 4A) when switches Q₁ and Q₂ of circuit 900 are kept OFF (non-conducting). In a turn-ON operation: the transistor starts in an OFF (non-conducting) steady state; at to, Q₄ is opened (switched to a non-conducting state) and Q₃ is closed (switched to a conducting state), causing V_{cc} to appear at full-bridge switched terminal 904B (a first gate-driving pulse); at t₁, Q₄ is closed and Q₃ is opened, causing full-bridge switched terminal 904B to fall to an intermediate value below Vₜₕ of the transistor; and at t₂, Q₄ is opened again and Q₃ is closed, causing V_{cc} to appear at full-bridge switched terminal 904B again (a second gate-driving pulse). A turn-OFF operation is analogous and will be understood by those skilled in the art on the basis of the description provided herein.

FIG. 11C is a schematic illustration of a number of circuit parameters of the FIG. 11A full-bridge circuit 900 when operating in an operating mode B wherein gate inductor L_{G} is precharged and then connected in series with L_{Par} and the gate 15 of the transistor being controlled to charge or discharge the gate capacitance Cᵢₛₛ (not shown) of the transistor being controlled. The amplitude of the current i_{LG} through inductor L_{G} may be selected such that the target voltage of v_{GS} (V_{GS_on}) is reached when the gate current i_{G} is near-zero. After the commutation of the FET being controlled, Q₃ and Q₄ are operated in a way to clamp v_{GS} to the target voltage v_{GS_on}. In a turn-ON operation, the transistor being controlled starts in an OFF (non-conducting) steady state. At t₀, Q₁ and Q₄ are in conducting states, creating current i_{LG} and charging inductor L_{G} while full-bridge switched terminal 904B remains at a low voltage and current i_{G} remains at zero because Q₄ is conducting and bypassing gate 15. At t₁, Q₁ and Q₄ are switched to non-conducting states and Q₂ is switched to a conducting state and inductor LG turns into a current source providing gate current i_{G}, charging the gate capacitance Cᵢₛₛ of the transistor being controlled and providing a first gate-driving voltage pulse at full-bridge switched terminal 904B. As the gate capacitance Cis, charges and v_{GS} increases, the currents i_{G} and i_{LG} decrease; at t₂, Q₂ is switched to non-conducting states and Q₃ is switched to a conducting state, thereby providing a second gate-driving voltage pulse at full-bridge switched terminal 904B and clamping v_{GS} to the target voltage v_{GS_on}. A turn-OFF operation is analogous and will be understood by those skilled in the art on the basis of the description provided herein. With this full-bridge operational mode, the commutation speed of the FET being controlled can be significantly increased, while maintaining near-zero oscillations in the gate circuitry.

FIG. 11D is a schematic illustration of a number of circuit parameters of the FIG. 11A full-bridge circuit 900 when operating in an operating mode C, which utilizes Q₁ and Q₂ to provide a pulse-width modulated (PWM) gate-driving voltage signal which controls the currents i_{G} and i_{LG} during the commutation. The PWM frequency of the gate-driving signal may be selected such that the PWM period is significantly shorter than the typical commutation time (switching time) of the transistor being controlled. For example, in some embodiments, the PWM period may be less than ⅓ of the period of the resonant tank defined by the parasitic inductance of the gate terminal and the gate capacitance (e.g. by Lₚₐᵣ and Cᵢₛₛ), less than ⅕ of this resonant tank period, or less than 1/10 of this resonant tank period. Because the PWM period is fast in comparison to the commutation time, the PWM signal gate driving signal applied during commutation may be considered to be a first voltage pulse having an “effective” amplitude dictated by a product of the PWM amplitude and duty cycle. The PWM parameters (which may include frequency, amplitude and duty cycle) may selected a such that i_{G} is near-zero when v_{GS} is at the target voltage v_{GS_on} at the conclusion of the commutation process. After the commutation of the transistor being controlled, Q₃ and Q₄ are operated in a way provide a second gate-driving voltage pulse at full-bridge terminal 904B and clamping v_{GS} to the target voltage v_{GS_on}.

In a turn-ON operation, the transistor being controlled starts in an OFF (non-conducting) steady state. Starting at to, Q₁ and Q₂ are alternatingly turned on and off, while Q₃ and Q₄ remain non-conducting, creating a first gate driving voltage pulse, which in turn causes i_{G}, i_{LG} and V_{GS} to increase. As v_{GS} increases, the effective voltage at full-bridge node 904B increases (relative to the effective voltage at full-bridge node 904A) and currents i_{G}, i_{LG} start to decrease again. At t₁, Q₁ and Q₂ are switched to non-conducting states and Q₃ is switched to a conducting state while Q₄ is maintained in a non-conducting state, thereby providing a second gate-driving voltage pulse at full-bridge terminal 904B and clamping v_{GS} to the target voltage v_{GS_on} in a manner analogous to that at t₂ of the embodiment shown in FIG. 11C. A turn-OFF operation is analogous and will be understood by those skilled in the art on the basis of the description provided herein. With this full-bridge operational mode, the commutation of the FET being controlled can be controlled with enhanced precision, which allows for improvements in slew-rate control and consequent benefits with respect to electromagnetic compatibility (EMC) and electromagnetic interference (EMI).

In another embodiment (not explicitly shown), Q₁ and Q₂ of full-bridge circuit 900 could be effectively left non-conducting and Q₃ and Q₄ could be controlled to provide a first voltage pulse having a first effective amplitude to full-bridge terminal 904B using a PWM signal during commutation and then could be operated such that Q₃ is switched to a conducting state while Q₄ is maintained in a non-conducting state, thereby providing a second gate-driving voltage pulse at full-bridge terminal 904B and clamping v_{GS} to the target voltage V_{GS} on in a manner analogous to that discussed in relation to FIGS. 11C and 11D. Like the embodiment of FIG. 11D, the PWM frequency of the gate-driving signal during commutation in this embodiment may be selected such that the PWM period is significantly shorter than the typical commutation time (switching time) of the transistor being controlled. For example, in some embodiments, the PWM period may be less than ⅓ of the period of the resonant tank defined by the parasitic inductance of the gate terminal and the gate capacitance (e.g. by Lₚₐᵣ and Cᵢₛₛ), less than ⅕ of this resonant tank period, or less than 1/10 of this resonant tank period. Because the PWM period is fast in comparison to the commutation time, the “effective” amplitude of the first gate-driving pulse may be dictated by a product of the PWM amplitude and duty cycle. The PWM parameters (which may include frequency, amplitude and duty cycle) may selected a such that i_{G} is near-zero when v_{GS} is at the target voltage v_{GS_on} at the conclusion of the commutation process. A turn-OFF operation is analogous and will be understood by those skilled in the art on the basis of the description provided herein. Those skilled in the art will appreciate that because this non-illustrated embodiment leaves Q₁ and Q₂ of full-bridge circuit 900 non-conducting and applies the multi-pulse gate-driving signal using Q₃ and Q₄, this embodiment could also be implemented using the half-bridge circuits with the pair of switches shown in FIG. 2A and FIG. 4A.

In some embodiments, the pulse-width modulation (PWM) parameters (e.g. frequency, amplitude and/or duty cycle) could be varied during a pulse (e.g. during the first pulse). An example implementation wherein a variation of PWM duty cycle is used during the first pulse of a turn-ON operation is shown in FIG. 11E). In the FIG. 11E example, the duty cycle (implemented by full-bridge switches Q₁ and Q₂ has three different duty cycles (D1, D2 and D3) during the first pulse. The second pulse of the FIG. 11E example is shown as being the same as that of the FIG. 11D embodiment. It will be appreciated that the three difference duty cycles of the FIG. 11E example result in three different “effective” amplitudes of the first pulse. A similar variation of PWM parameters could be implemented in the first pulse of a turn-OFF operation. Variation of PWM parameters could also be used in the switches Q₃ and Q₄ of full-bridge circuit 900 (e.g. with Q₁ and Q₂ non-conducting), which is effectively the same as varying the PWM parameters in this manner in the half-bridge circuits with the pair of switches shown in FIG. 2A and FIG. 4A.

PWM is described above for use during the first pulse to provide an effective amplitude during the first pulse and the second pulse is described as clamping the voltage (of the relevant node). In some embodiments, PWM may additionally or alternatively be used in the second pulse to provide the second pulse with an effective amplitude.

The description to this point describes open loop selection of various parameters of the multi-pulse gate-driving signal v_{DR} based on specified (e.g. by a datasheet) or measured parameters of other components. There may be a desire in practice, to tune the parameters of the multi-pulse gate-driving signal v_{DR} using a closed loop control solution which may help to mitigate drift or other variation of the parameters of other components which may be caused, for example, by aging, temperature changes and changes in the operating points of various components.

FIG. 12 is a schematic depiction of a closed loop system 910 which involves measurement of one or more of i_{G}, V_{GS}, i_{D}, V_{DS}, V_{DR} and/or temperature or other parameters (not expressly shown in FIG. 12) and feeding back this information to a controller (shown as a microcontroller MCU in the illustrated example embodiment) which can be configured to implement a suitable control mechanism to adapt the multi-pulse parameters (e.g. pulse amplitude, pulse voltage levels, pulse duration, temporal pulse separation, pulse frequency, pulse duty cycle, charge time and/or the like (e.g. t_{A}, t_{B} described above)) of the v_{DR} pulses according to a particular embodiment. Such a control mechanism may comprise any suitable control mechanism such as a linear (e.g. PID) controller and/or a non-linear controller and may use pre-defined and/or dynamic look-up tables (LUTs). The measured feedback may be continuous, discrete or binary. The controller and/or measurement function may be implemented as an analog circuit, as a digital scheme or a combination of analog and digital. In the case of a digital controller, the implementation can be performed through a microcontroller unit (MCU) as is the case in the illustrated FIG. 12 embodiment, which may comprise either the central MCU of some system of which the FET under control is a part or a dedicated MCU which is solely responsible for the proposed multi-pulse gate-driving scheme. Since power conversion applications typically use an MCU for operation, an implementation in a central MCU may be favorable, although not necessary. It may be desirable for the MCU to be physically or electrically close to the driver for performance and/or signal integrity. These MCUs can be implemented as digital signal processors (DSPs), field programmable gate arrays (FPGAs), complex programmable logic devices (CPLDs) and/or the like and any combination thereof.

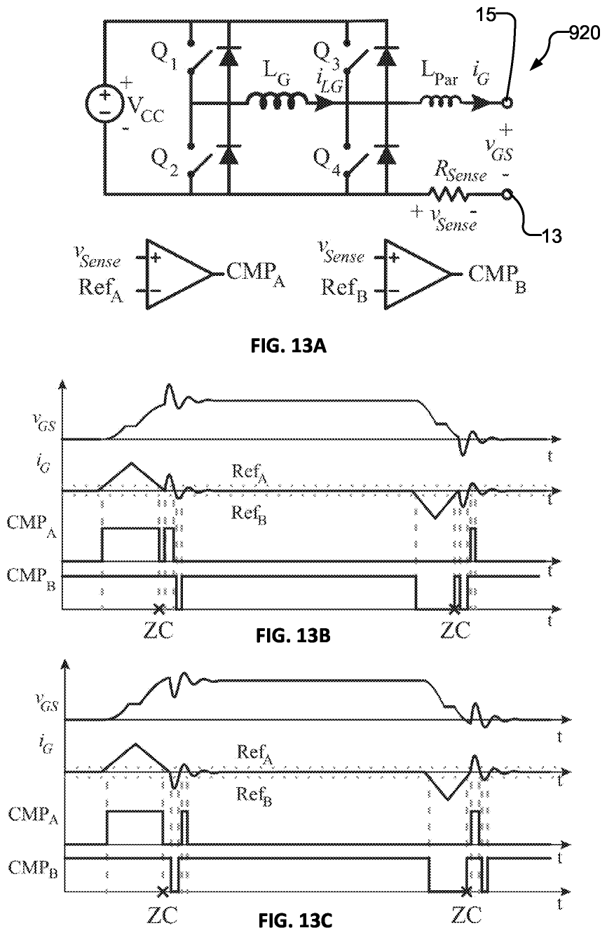

FIGS. 13A, 13B and 13C (collectively FIG. 13) respectively depict a window comparator circuit 910 implementing i_{G} feedback according to a particular embodiment, waveforms for various parameters when the transferred charge is too low and waveforms for various parameters when the transferred charge is too high. FIG. 13A illustrates the current sensing resistor Rₛₑₙₛₑ, which produces the sensing voltage vₛₑₙₛₑ and two comparators (CMP_{A} and CMP_{B}) that operate with two corresponding reference voltages Ref_{A} and Ref_{B}. With these comparators (CMP_{A} and CMP_{B}), the zero-crossing (ZC) of i_{G} can be detected (ZC=CMP_{A} XOR CMP_{B}) where XOR is the exclusive OR operator, which in turn may be utilized to determine the end of the proposed modulation as well as the fine-tuning.

FIG. 13B depicts the operation of the feedback when the transferred charge is too low. It can be seen from FIG. 13B that, at the turn-ON ZC, the current i_{G} will have an oscillation starting with positive amplitude to account for the lack of charge in Cᵢₛₛ necessary to complete the commutation. This results in an additional ZC, where the current i_{G} transitions from positive to negative direction. This direction is then later utilized to adjust the timing parameter t_{A} by an incremental time-adjustment parameter p. Similarly, it can be seen at the turn-OFF ZC that the current i_{G} will experience an oscillation starting with negative amplitude to account to account for the lack of charge in Cᵢₛₛ to complete the commutation. This results in an additional ZC, where the current i_{G} transitions from negative to positive direction. This direction is then later utilized to adjust the timing parameter t_{B} by an incremental time-adjustment parameter p. FIG. 13C depicts the operation of the feedback when the transferred charge is too large. This operation is analogous to that shown in FIG. 13B and is omitted for brevity.

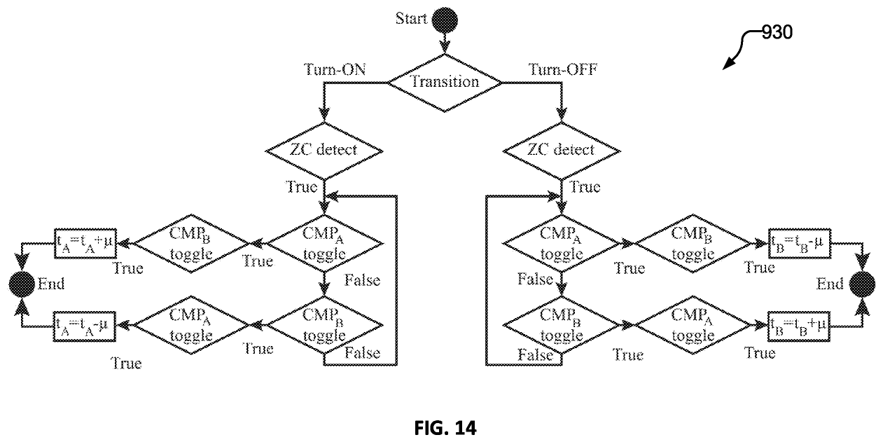

FIG. 14 is a flow chart illustrating a methodology that may be used to implement control of the multi-pulse parameters t_{A}, t_{B} using the i_{G} feedback provided by the window comparator illustrated in the FIG. 13A circuit 920 according to a particular embodiment. In principle, after a ZC-event, the states of the comparators (CMP_{A} and CMP_{B}) are observed and depending on the sequence of comparator changes, the timing parameters t_{A} and/or t_{B} are adjusted accordingly. The update of the timing parameters may be performed cycle-by-cycle and thus should track any changes in operating point swiftly.

This disclosure describes the use of standard and off the shelve components for its implementation. Although, this showcases the ease of adaptability of the multi-pulse gate-driving concept, there may be options of further harnessing the multi-pulse gate-driving concept with custom integrated circuits (ICs) and/or custom designed switches, which may further enhance the characteristics of particular embodiments. For example, potential candidates for driver ICs may comprise drivers based on gallium nitride (GaN), as they provide very fast turn on and off times. Further, the above-described closed loop control may be implemented within an custom IC that includes the measurement of the needed parameters and control logic. This option may or may not include isolation of driving features. This IC may be included within a power switch or a power switch may be implemented on an IC.

Further, some power switches come with an internal gate resistor for controllability. With the proposed multi-pulse gate-driving scheme, power switches may want to remove this internal gate resistance for performance improvement. Furthermore, additional gate circuitry for performance and reliability enhancements may be incorporated into particular embodiments. For instance, clamping circuits may be implemented to improve the reliability of the circuit protecting overvoltages. Moreover, additional capacitance may be added to the switch for enhanced controllability and added margins towards safe operation of the power switch. Also, multiple inductors may be implemented to allow for different transitions of the on and off transients. These inductors may also be used to alter the on or off trajectory of the transient as they may or may not be enabled in the circuit through control switches.

In the multi-pulse strategies described above, the gate-driving strategy involve two ON pulses for a turn-ON operation and two OFF pulses for a turn-OFF operation. In other embodiments, multiple (more than two) ON pulses may be used for a turn-ON operation and/or multiple (more than two) OFF pulses may be used for a turn-OFF operation. Both the two pulse embodiments and the train of (more than two) pulses can be implemented using open loop (predefined) or close loop (adaptive) parameters. With these strategies, conversion efficiency and electromagnetic interference (EMI) may be controlled through software, which allows for tremendous advantages in the power electronics community. This may lead to reduction of EMI and voltage stress without compromising efficiency or vice versa. Moreover, the driving can be adapted on the operating condition leading to enhanced controllability of power conversion applications.

Where a component (e.g. a software module, processor, assembly, device, circuit, etc.) is referred to herein, unless otherwise indicated, reference to that component (including a reference to a “means”) should be interpreted as including as equivalents of that component any component which performs the function of the described component (i.e., that is functionally equivalent), including components which are not structurally equivalent to the disclosed structure which performs the function in the illustrated exemplary embodiments of the invention.

Embodiments of the invention may be implemented using specifically designed hardware, configurable hardware, programmable data processors configured by the provision of software (which may optionally comprise “firmware”) capable of executing on the data processors, special purpose computers or data processors that are specifically programmed, configured, or constructed to perform one or more steps in a method as explained in detail herein and/or combinations of two or more of these. Examples of specifically designed hardware are: logic circuits, application-specific integrated circuits (“ASICs”), large scale integrated circuits (“LSIs”), very large scale integrated circuits (“VLSIs”), and the like. Examples of configurable hardware are: one or more programmable logic devices such as programmable array logic (“PALs”), programmable logic arrays (“PLAs”), and field programmable gate arrays (“FPGAs”). Examples of programmable data processors are: microprocessors, digital signal processors (“DSPs”), embedded processors, graphics processors, math co-processors, general purpose computers, server computers, cloud computers, mainframe computers, computer workstations, and the like. For example, one or more data processors in a control circuit for a device may implement methods as described herein by executing software instructions in a program memory accessible to the processors.

Processing may be centralized or distributed. Where processing is distributed, information including software and/or data may be kept centrally or distributed. Such information may be exchanged between different functional units by way of a communications network, such as a Local Area Network (LAN), Wide Area Network (WAN), or the Internet, wired or wireless data links, electromagnetic signals, or other data communication channel.

The invention may also be provided in the form of a program product. The program product may comprise any non-transitory medium which carries a set of computer-readable instructions which, when executed by a data processor, cause the data processor to execute a method of the invention. Program products according to the invention may be in any of a wide variety of forms. The program product may comprise, for example, non-transitory media such as magnetic data storage media including floppy diskettes, hard disk drives, optical data storage media including CD ROMs, DVDs, electronic data storage media including ROMs, flash RAM, EPROMs, hardwired or preprogrammed chips (e.g., EEPROM semiconductor chips), nanotechnology memory, or the like. The computer-readable signals on the program product may optionally be compressed or encrypted.

In some embodiments, the invention may be implemented in software. For greater clarity, “software” includes any instructions executed on a processor, and may include (but is not limited to) firmware, resident software, microcode, code for configuring a configurable logic circuit, applications, apps, and the like. Both processing hardware and software may be centralized or distributed (or a combination thereof), in whole or in part, as known to those skilled in the art. For example, software and other modules may be accessible via local memory, via a network, via a browser or other application in a distributed computing context, or via other means suitable for the purposes described above.

Software and other modules may reside on servers, workstations, personal computers, tablet computers, and other devices suitable for the purposes described herein.

The invention provides a number of non-limiting aspects. Non-limiting aspects of the invention comprise:
1. A method for operating a semiconductor switching device having a gate capacitance to switch the device from a starting steady state to an ending steady state that is different from the starting steady state, the method comprising:
   applying a first gate-driving voltage pulse to a gate of the device when the device is in the starting steady state, the first voltage pulse having a first effective amplitude a first pulse duration t_{A};
   applying a second gate-driving voltage pulse to the gate after applying the first gate driving pulse, the second gate-driving voltage pulse having a second effective amplitude and a second pulse duration,
   wherein the second voltage pulse is applied during a transition of the device between the starting steady state and the ending steady state.
2. The method of aspect 1 or any other aspect herein wherein the first effective amplitude crosses from a starting state value that is below a threshold voltage Vₜₕ associated with the device to a first pulse value that is above the threshold voltage Vₜₕ.
3. The method of any of aspects 1 to 2 or any other aspect herein wherein the second gate-driving voltage pulse has a second effective amplitude that crosses from an intermediate value that is below the threshold voltage Vₜₕ to a second pulse value that is above the threshold voltage Vₜₕ.
4. The method of aspect 1 or any other aspect herein wherein the first effective amplitude is from a starting state value that is above a threshold voltage Vₜₕ associated with the device to a first pulse value that is below the threshold voltage Vₜₕ.
5. The method of any of aspects 1 and 4 or any other aspect herein wherein the second gate-driving voltage pulse has a second effective amplitude that crosses from an intermediate value that is above the threshold voltage Vₜₕ to a second pulse value that is below the threshold voltage Vₜₕ.
6. The method of any one of aspects 3 and 5 or any other aspect herein wherein the intermediate value is about equal to the starting state value.
7. The method of any one of aspects 1 to 6 or any other aspect herein wherein the first pulse duration t_{A} is less than a time that it takes for the device to reach the ending steady state.
8. The method of any one of aspects 1 to 7 or any other aspect herein wherein the second gate-driving pulse has a duration that is sufficiently long for the device to reach the ending steady state during the second gate-driving pulse.
9. The method of any one of aspects 1 to 8 or any other aspect herein comprising maintaining the gate-driving voltage at an intermediate value for a period of time t_{B} after a conclusion of the first gate-driving pulse and before applying the second gate-driving voltage pulse.
10. The method of aspect 9 or any other aspect herein wherein the second gate-driving voltage pulse has a second effective amplitude that crosses from the intermediate value that is below the threshold voltage Vₜₕ to a second pulse value that is above the threshold voltage Vₜₕ.
11. The method of aspect 9 or any other aspect herein wherein the second gate-driving voltage pulse has a second effective amplitude that crosses from the intermediate value that is above the threshold voltage Vₜₕ to a second pulse value that is below the threshold voltage Vₜₕ.
12. The method of any one of aspects 9 to 11 or any other aspect herein wherein the intermediate value is the same at the starting state value.
13. The method of any one of aspects 1 to 12 or any other aspect herein wherein the first effective amplitude is the same as the second effective amplitude.
14. The method of any one of aspects 1 to 13 or any other aspect herein, wherein the method is applied to a turn-ON operation, the device is non-conducting (e.g. between drain and source) in the starting steady state, the device is conducting (e.g. between drain and source) in the ending steady state, the starting state value and the intermediate value are less than the threshold voltage Vₜₕ and the first pulse value and the second pulse value are greater than the threshold voltage Vₜₕ.
15. The method of any one of aspects 1 to 13 or any other aspect herein, wherein the method is applied to a turn-OFF operation, the device is conducting (e.g. between drain and source) in the starting steady state, the device is non-conducting (e.g. between drain and source) in the ending steady state, the starting state value and the intermediate value are greater than the threshold voltage Vₜₕ and the first pulse value and the second pulse value are less than the threshold voltage Vₜₕ.
16. The method of any one of aspects 1 to 15 or any other aspect herein comprising applying one or more additional gate-driving voltage pulses to the gate after applying the first gate driving pulse and prior to applying the second gate driving pulse.
17. The method of aspect 16 or any other aspect herein wherein the one or more additional gate-driving pulses have the same pulse parameters (e.g. amplitude and duration) as the first pulse.
18. The method of aspect 16 or any other aspect herein wherein at least one of the one or more additional gate-driving pulses has different pulse parameters (e.g. amplitude and duration) as the first pulse.
19. The method of any one of aspects 16 to 18 wherein temporal pulse-spacing between the first pulse, the one or more additional pulses and the second pulse is the same.
20. The method of any one of aspects 16 to 18 wherein temporal pulse-spacing between at least a first temporally adjacent pair of the first pulse, the one or more additional pulses and the second pulse is different than at least a second temporally adjacent pair of the first pulse, the one or more additional pulses and the second pulse.
21. The method of any one of aspects 1 to 20 or any other aspect herein wherein applying the first and second gate-driving pulses comprises controlling a gate-control voltage source.
22. The method of aspect 21 or any other aspect herein wherein controlling the gate-control voltage source comprises controlling a half-bridge circuit having its switched terminal electrically connected to the gate.
23. The method of aspect 22 or any other aspect herein wherein the electrical connection between the switched terminal and the gate is made by an electrically conductive connection wherein any resistance between the switched terminal and the gate is the inherent internal resistance of the electrically conductive connection, including, possibly, any internal driver and/or MOSFET connections of the half-bridge circuit.
24. The method of any one of aspects 22 to 23 or any other aspect herein wherein any inductance between the switched terminal and the gate is the inherent internal inductance Lₚₐᵣ of the electrically conductive connection, including, possibly, any internal driver and/or MOSFET connections of the half-bridge circuit.
25. The method of any one of aspects 22 to 24 or any other aspect herein wherein applying the first pulse comprises controlling the half-bridge circuit to provide a pulse-width modulated (PWM) signal at the switched terminal and wherein the first effective amplitude is based on one or more of the parameters (e.g. pulse amplitude, frequency and/or duty cycle) of the PWM signal.
26. The method of aspect 25 or any other aspect herein comprising controlling the half-bridge circuit to vary one or more of the parameters (e.g. pulse amplitude, frequency and/or duty cycle) of the PWM signal during the first pulse duration t_{A}.
27. The method of any one of aspects 25 to 26 or any other aspect herein wherein applying the second pulse comprises controlling the half-bridge to clamp the voltage at the switched terminal to the second effective amplitude when a gate current i_{G} is at or near zero.
28. The method of aspect 21 or any other aspect herein wherein controlling the gate-control voltage source comprises controlling a full-bridge circuit.
29. The method of aspect 28 or any other aspect herein wherein the full-bridge circuit has one of its switched terminals electrically connected to the gate.
30. The method of aspect 29 or any other aspect herein wherein the electrical connection between the one of the switched terminals and the gate is made by an electrically conductive connection wherein any resistance between the one of the switched terminals and the gate is the inherent internal resistance of the electrically conductive connection, including, possibly, any internal driver and/or MOSFET connections of the full-bridge circuit.
31. The method of any one of aspects 29 to 30 or any other aspect herein wherein any inductance between the one of the switched terminals and the gate is the inherent internal inductance Lₚₐᵣ of the electrically conductive connection, including, possibly, any internal driver and/or MOSFET connections of the full-bridge circuit.
32. The method of any one of aspects 29 to 31 or any other aspect herein wherein the full-bridge circuit comprises an inductor LG connected between the one of the switched terminals and a second one of the switched terminals of the full-bridge.
33. The method of aspect 32 or any other aspect herein wherein applying the first gate-driving pulse comprises: controlling the full-bridge to charge the inductor LG prior to applying the first pulse, and controlling the full-bridge to cause the inductor LG to act as a current source when the first pulse is applied.
34. The method of aspect 33 or any other aspect herein wherein applying the second pulse comprises controlling the full-bridge to clamp the voltage at the one of the switched terminals to the second effective amplitude when a gate current i_{G} is at or near zero.
35. The method of aspect 32 or any other aspect herein wherein applying the first pulse comprises controlling the full-bridge circuit to provide a pulse-width modulated (PWM) signal at the second one of the switched terminals and wherein the first effective amplitude is based on one or more of the parameters (e.g. pulse amplitude, frequency and/or duty cycle) of the PWM signal.
36. The method of aspect 35 or any other aspect herein comprising controlling the full-bridge circuit to vary one or more of the parameters (e.g. pulse amplitude, frequency and/or duty cycle) of the PWM signal during the first pulse duration t_{A}.
37. The method of any one of aspects 35 to 36 or any other aspect herein wherein applying the second pulse comprises controlling the full-bridge to clamp the voltage at the one of the switched terminals to the second effective amplitude when a gate current i_{G} is at or near zero.
38. The method of any one of aspects 1 to 37 or any other aspect herein comprising repeatedly applying the method to switch the device from the starting state to the ending state and to switch the device from the ending state back to the starting state.
39. The method of aspect 38 or any other aspect herein wherein the repeated application of the method is used in one of: a switch-mode power supply; a digital communication circuit; a discrete amplifier; a signal conditioning circuit; a LED drive; and a digital clock.
40. The method of any one of aspects 38 to 39 or any other aspect herein comprising:
   sensing a value of at least one of a voltage at a node of the device and a current through a node of the device; and
   adjusting one or more parameters of at least one of the first gate-driving pulse and the second gate-driving pulse based at least in part on the sensed value.
41. The method of aspect 40 or any other aspect herein wherein the node of the device is one of a gate, a source or a drain of a transistor.
42. The method of any one of aspects 38 to 39 or any other aspect herein comprising:
   sensing a temperature correlated with a temperature of the device; and
   adjusting one or more parameters of at least one of the first gate-driving pulse and the second gate-driving pulse based at least in part on the sensed value.
43. The method of any one of aspects 40 to 42 or any other aspect herein wherein adjusting the one or more parameters of at least one of the first gate-driving pulse and the second gate-driving pulse based at least in part on the sensed value is performed by a controller.
44. The method of aspect 43 or any other aspect herein wherein the controller configured to implement a control algorithm based at least in part on a desired value for the sensed value.
45. The method of any one of aspects 40 to 44 or any other aspect herein wherein the one or more parameters of the at least one of the first gate-driving pulse and the second gate-driving pulse comprises the first pulse duration t_{A}.
46. The method of any one of aspects 40 to 45 or any other aspect herein wherein the one or more parameters of the at least one of the first gate-driving pulse and the second gate-driving pulse comprises the first effective amplitude.
47. The method of any one of aspects 40 to 46 or any other aspect herein wherein the one or more parameters of the at least one of the gate-driving first pulse and the second gate-driving pulse comprises a period of time t_{B} after a conclusion of the first gate-driving pulse and before applying the second gate-driving voltage pulse during which the gate-driving voltage is maintained at the intermediate value.
48. The method of any one of aspects 40 to 47 or any other aspect herein wherein the one or more parameters of the at least one of the first gate-driving pulse and the second gate-driving pulse comprises the second effective amplitude.
49. The method of any one of aspects 40 to 48 or any other aspect herein wherein applying the first gate-driving pulse comprises applying a first series of pulse-width modulated (PWM) voltage pulses to the gate, the first series of pulse-width modulated voltage pulses having first PWM parameters (e.g. a first PWM frequency, a first PWM duty cycle and/or a first PWM amplitude) which achieve the first effective amplitude and wherein the one or more parameters of the at least one of the first gate-driving pulse and the second gate-driving pulse comprises at least one of the first PWM parameters.
50. The method of any one of aspects 40 to 49 or any other aspect herein wherein applying the second gate-driving pulse comprises applying a second series of pulse-width modulated (PWM) voltage pulses to the gate, the second series of pulse-width modulated voltage pulses having second PWM parameters (e.g. a second PWM frequency, a second PWM duty cycle and/or a second PWM amplitude) which achieve the second effective amplitude and wherein the one or more parameters of the at least one of the first gate-driving pulse and the second gate-driving pulse comprises at least one of the second PWM parameters.
51. A circuit for operating a semiconductor switching device having a gate capacitance to switch the device from a starting steady state to an ending steady state that is different from the starting steady state, the circuit comprising:
   a gate-control voltage source connected to a gate of the transistor by an electrically conductive (e.g. metal) connection between an output of the gate-control voltage source and the gate;
   a controller connected to the gate-control voltage source, the controller configured to:
      cause the gate-control voltage source to apply a first gate-driving voltage pulse to a gate of the device when the device is in the starting steady state, the first voltage pulse having a first effective amplitude a first pulse duration t_{A};
      cause the gate-control voltage source to apply a second gate-driving voltage pulse to the gate after applying the first gate driving pulse, the second gate-driving voltage pulse having a second effective amplitude and a second pulse duration;
   wherein the second voltage pulse is applied during a transition of the device between the starting steady state and the ending steady state.
52. The circuit of aspect 51 or any other aspect herein wherein the gate-control voltage source comprises a half-bridge circuit comprising a pair of switches and a switched terminal therebetween, the switched terminal electrically connected to the gate by the electrically conductive connection.
53. The circuit of aspect 52 or any other aspect herein wherein any resistance between the switched terminal and the gate is the inherent internal resistance of the electrically conductive connection, including, possibly, any internal driver and/or MOSFET connections of the half-bridge circuit.
54. The circuit of any one of aspects 52 to 53 or any other aspect herein wherein any inductance between the switched terminal and the gate is the inherent internal inductance Lₚₐᵣ of the electrically conductive connection, including, possibly, any internal driver and/or MOSFET connections of the half-bridge circuit.
55. The circuit of any one of aspects 52 to 54 or any other aspect herein wherein the controller is configured to cause the gate-control voltage source to apply the first pulse by controlling the switches of the half-bridge circuit to provide a pulse-width modulated (PWM) signal at the switched terminal and wherein the first effective amplitude is based on one or more of the parameters (e.g. pulse amplitude, frequency and/or duty cycle) of the PWM signal.
56. The circuit of aspect 55 or any other aspect herein wherein the controller is configured to control the switches of the half-bridge circuit to vary one or more of the parameters (e.g. pulse amplitude, frequency and/or duty cycle) of the PWM signal during the first pulse duration t_{A}.
57. The circuit of any one of aspects 55 to 56 or any other aspect herein wherein the controller is configured to cause the gate-control voltage source to apply the second pulse by controlling the switches of the half-bridge circuit to clamp the voltage at the switched terminal to the second effective amplitude when a gate current i_{G} is at or near zero.
58. The circuit of aspect 51 or any other aspect herein wherein the gate-control voltage source comprises a full-bridge circuit comprising a pair of branches, each branch comprising a pair of switches and a switched terminal therebetween.
59. The circuit of aspect 58 or any other aspect herein wherein one of the switched terminals of the full-bridge circuit is electrically connected to the gate.
60. The circuit of aspect 59 or any other aspect herein wherein the electrical connection between the one of the switched terminals and the gate is made by an electrically conductive connection wherein any resistance between the one of the switched terminals and the gate is the inherent internal resistance of the electrically conductive connection, including, possibly, any internal driver and/or MOSFET connections of the full-bridge circuit.
61. The circuit of any one of aspects 59 to 60 or any other aspect herein wherein any inductance between the one of the switched terminals and the gate is the inherent internal inductance Lₚₐᵣ of the electrically conductive connection, including, possibly, any internal driver and/or MOSFET connections of the full-bridge circuit.
62. The circuit of any one of aspects 59 to 61 or any other aspect herein wherein the full-bridge circuit comprises an inductor LG connected between the switched terminals of the full-bridge.
63. The circuit of aspect 62 or any other aspect herein wherein the controller is configured to cause the gate-control voltage source to apply the first pulse by controlling the switches of the full-bridge to charge the inductor LG prior to applying the first pulse; and controlling the switches of the full-bridge to cause the inductor LG to act as a current source when the first pulse is applied.
64. The circuit of aspect 63 or any other aspect herein wherein the controller is configured to cause the gate-control voltage source to apply the second pulse by controlling the switches of the full-bridge to clamp the voltage at the one of the switched terminals to the second effective amplitude when a gate current i_{G} is at or near zero.
65. The circuit of aspect 62 or any other aspect herein wherein the controller is configured to cause the gate-control voltage source to apply the first pulse by controlling the switches of the full-bridge circuit to provide a pulse-width modulated (PWM) signal at the second one of the switched terminals and wherein the first effective amplitude is based on one or more of the parameters (e.g. pulse amplitude, frequency and/or duty cycle) of the PWM signal.
66. The circuit of aspect 65 or any other aspect herein wherein the controller is configured to control the switches of the full-bridge circuit to vary one or more of the parameters (e.g. pulse amplitude, frequency and/or duty cycle) of the PWM signal during the first pulse duration t_{A}.
67. The circuit of any one of aspects 65 to 66 or any other aspect herein wherein the controller is configured to cause the gate-control voltage source to apply the second pulse by controlling the switches of the full-bridge to clamp the voltage at the one of the switched terminals to the second effective amplitude when a gate current i_{G} is at or near zero.
68. The circuit of any one of aspects 51 to 67 or any other aspect herein wherein the first effective amplitude crosses from a starting state value that is below a threshold voltage Vₜₕ associated with the device to a first pulse value that is above the threshold voltage Vₜₕ.
69. The circuit of 51 to 68 wherein the second gate-driving voltage pulse has a second effective amplitude that crosses from an intermediate value that is below the threshold voltage Vₜₕ to a second pulse value that is above the threshold voltage Vₜₕ.
70. The circuit of any one of aspects 51 to 67 or any other aspect herein wherein the first effective amplitude crosses from a starting state value that is above a threshold voltage Vₜₕ associated with the device to a first pulse value that is below the threshold voltage Vₜₕ.
71. The circuit of any one of aspects 51 to 67 and 70 or any other aspect herein wherein the second gate-driving voltage pulse has a second effective amplitude that crosses from an intermediate value that is above the threshold voltage Vₜₕ to a second pulse value that is below the threshold voltage Vₜₕ.
72. The circuit of any one of aspects 69 and 71 or any other aspect herein wherein the intermediate value is about equal to the starting state value.
73. The circuit of any one of aspects 51 to 72 or any other aspect herein wherein the controller is configured to control the first pulse duration tA to be less than a time that it takes for the device to reach the ending steady state.
74. The circuit of any one of aspects 51 to 73 or any other aspect herein wherein the controller is configured to control the second gate-driving pulse have a duration that is sufficiently long for the device to reach the ending steady state during the second gate-driving pulse.
75. The circuit of any one of aspects 51 to 74 or any other aspect herein wherein the controller is configured to maintain the gate-driving voltage at an intermediate value for a period of time t_{B} after a conclusion of the first gate-driving pulse and before causing the gate-control voltage source to apply the second gate-driving voltage pulse.
76. The circuit of aspect 75 or any other aspect herein wherein the second gate-driving voltage pulse has a second effective amplitude that crosses from the intermediate value that is below the threshold voltage Vₜₕ to a second pulse value that is above the threshold voltage Vₜₕ.
77. The circuit of aspect 75 or any other aspect herein wherein the second gate-driving voltage pulse has a second effective amplitude that crosses from the intermediate value that is above the threshold voltage Vₜₕ to a second pulse value that is below the threshold voltage Vₜₕ.
78. The circuit of any one of aspects 75 to 77 or any other aspect herein wherein the intermediate value is the same at the starting state value.
79. The circuit of any one of aspects 51 to 78 or any other aspect herein wherein the first effective amplitude is the same as the second effective amplitude.
80. The circuit of any one of aspects 51 to 79 or any other aspect herein, wherein the controller is configured to implement a turn-ON operation, the device is non-conducting (e.g. between drain and source) in the starting steady state, the device is conducting (e.g. between drain and source) in the ending steady state, the starting state value and the intermediate value are less than the threshold voltage Vₜₕ and the first pulse value and the second pulse value are greater than the threshold voltage Vₜₕ.
81. The circuit of any one of aspects 51 to 79 or any other aspect herein, wherein the controller is configured to implement a turn-OFF operation, the device is conducting (e.g. between drain and source) in the starting steady state, the device is non-conducting (e.g. between drain and source) in the ending steady state, the starting state value and the intermediate value are greater than the threshold voltage Vₜₕ and the first pulse value and the second pulse value are less than the threshold voltage Vₜₕ.
82. The circuit of any one of aspects 51 to 81 or any other aspect herein wherein the controller is configured to apply one or more additional gate-driving voltage pulses to the gate after applying the first gate driving pulse and prior to applying the second gate driving pulse.
83. The circuit of aspect 82 or any other aspect herein wherein the one or more additional gate-driving pulses have the same pulse parameters (e.g. amplitude and duration) as the first pulse.
84. The circuit of aspect 82 or any other aspect herein wherein at least one of the one or more additional gate-driving pulses has different pulse parameters (e.g. amplitude and duration) as the first pulse.
85. The circuit of any one of aspects 82 to 84 wherein temporal pulse-spacing between the first pulse, the one or more additional pulses and the second pulse is the same.
86. The circuit of any one of aspects 82 to 84 wherein temporal pulse-spacing between at least a first temporally adjacent pair of the first pulse, the one or more additional pulses and the second pulse is different than at least a second temporally adjacent pair of the first pulse, the one or more additional pulses and the second pulse.
87. The circuit of any one of aspects 51 to 86 or any other aspect herein wherein the controller is configured to repeatedly switch the device from the starting state to the ending state and to switch the device from the ending state back to the starting state.
88. The circuit of aspect 87 or any other aspect herein used in one of: a switch-mode power supply; a digital communication circuit; a discrete amplifier; a signal conditioning circuit; a LED drive; and a digital clock.
89. The circuit of any one of aspects 87 to 88 or any other aspect herein comprising:
   a sensor connected to sense a value of at least one of a voltage at a node of the device and a current through a node of the device;
   wherein the controller is configured to adjust one or more parameters of at least one of the first gate-driving pulse and the second gate-driving pulse based at least in part on the sensed value.
90. The circuit of aspect 89 or any other aspect herein wherein the node of the device is one of a gate, a source or a drain of a transistor.
91. The circuit of any one of aspects 87 to 88 or any other aspect herein comprising:
   a sensor connected to sense a temperature correlated with a temperature of the device; and
   wherein the controller is configured to adjust one or more parameters of at least one of the first gate-driving pulse and the second gate-driving pulse based at least in part on the sensed value.
92. The circuit of any one of aspects 89 to 91 or any other aspect herein wherein the controller configured to implement a control algorithm based at least in part on a desired value for the sensed value.
93. The circuit of any one of aspects 89 to 92 or any other aspect herein wherein the one or more parameters of the at least one of the first gate-driving pulse and the second gate-driving pulse comprises the first pulse duration t_{A}.
94. The circuit of any one of aspects 89 to 93 or any other aspect herein wherein the one or more parameters of the at least one of the first gate-driving pulse and the second gate-driving pulse comprises the first effective amplitude.
95. The circuit of any one of aspects 89 to 94 or any other aspect herein wherein the one or more parameters of the at least one of the gate-driving first pulse and the second gate-driving pulse comprises a period of time t_{B} after a conclusion of the first gate-driving pulse and before applying the second gate-driving voltage pulse during which the gate-driving voltage is maintained at the intermediate value.
96. The circuit of any one of aspects 89 to 95 or any other aspect herein wherein the one or more parameters of the at least one of the first gate-driving pulse and the second gate-driving pulse comprises the second effective amplitude.
97. The circuit of any one of aspects 89 to 96 or any other aspect herein wherein the controller is configured to apply the first gate-driving pulse by applying a first series of pulse-width modulated (PWM) voltage pulses to the gate, the first series of pulse-width modulated voltage pulses having first PWM parameters (e.g. a first PWM frequency, a first PWM duty cycle and/or a first PWM amplitude) which achieve the first effective amplitude and wherein the one or more parameters of the at least one of the first gate-driving pulse and the second gate-driving pulse comprises at least one of the first PWM parameters.
98. The circuit of any one of aspects 89 to 97 or any other aspect herein wherein the controller is configured to apply the second gate-driving pulse by applying a second series of pulse-width modulated (PWM) voltage pulses to the gate, the second series of pulse-width modulated voltage pulses having second PWM parameters (e.g. a second PWM frequency, a second PWM duty cycle and/or a second PWM amplitude) which achieve the second effective amplitude and wherein the one or more parameters of the at least one of the first gate-driving pulse and the second gate-driving pulse comprises at least one of the second PWM parameters.
99. Apparatus having any new and inventive feature, combination of features, or sub-combination of features as described herein.
100. Methods having any new and inventive steps, acts, combination of steps and/or acts or sub-combination of steps and/or acts as described herein.

### INTERPRETATION OF TERMS

Unless the context clearly requires otherwise, throughout the description and the claims:
“comprise”, “comprising”, and the like are to be construed in an inclusive sense, as opposed to an exclusive or exhaustive sense; that is to say, in the sense of “including, but not limited to”;
“connected”, “coupled”, or any variant thereof, means any connection or coupling, either direct or indirect, between two or more elements; the coupling or connection between the elements can be physical, logical, or a combination thereof;
“herein”, “above”, “below”, and words of similar import, when used to describe this specification, shall refer to this specification as a whole, and not to any particular portions of this specification;
“or”, in reference to a list of two or more items, covers all of the following interpretations of the word: any of the items in the list, all of the items in the list, and any combination of the items in the list;
the singular forms “a”, “an”, and “the” also include the meaning of any appropriate plural forms. These terms (“a”, “an”, and “the”) mean one or more unless stated otherwise;
“and/or” is used to indicate one or both stated cases may occur, for example A and/or B includes both (A and B) and (A or B);
“approximately” when applied to a numerical value means the numerical value±10%;
where a feature is described as being “optional” or “optionally” present or described as being present “in some embodiments” it is intended that the present disclosure encompasses embodiments where that feature is present and other embodiments where that feature is not necessarily present and other embodiments where that feature is excluded. Further, where any combination of features is described in this application this statement is intended to serve as antecedent basis for the use of exclusive terminology such as “solely,” “only” and the like in relation to the combination of features as well as the use of “negative” limitation(s)” to exclude the presence of other features; and
“first” and “second” are used for descriptive purposes and cannot be understood as indicating or implying relative importance or indicating the number of indicated technical features.

Words that indicate directions such as “vertical”, “transverse”, “horizontal”, “upward”, “downward”, “forward”, “backward”, “inward”, “outward”, “left”, “right”, “front”, “back”, “top”, “bottom”, “below”, “above”, “under”, and the like, used in this description and any accompanying claims (where present), depend on the specific orientation of the apparatus described and illustrated. The subject matter described herein may assume various alternative orientations. Accordingly, these directional terms are not strictly defined and should not be interpreted narrowly.

Where a range for a value is stated, the stated range includes all sub-ranges of the range. It is intended that the statement of a range supports the value being at an endpoint of the range as well as at any intervening value to the tenth of the unit of the lower limit of the range, as well as any subrange or sets of sub ranges of the range unless the context clearly dictates otherwise or any portion(s) of the stated range is specifically excluded. Where the stated range includes one or both endpoints of the range, ranges excluding either or both of those included endpoints are also included in the invention.

Certain numerical values described herein are preceded by “about”. In this context, “about” provides literal support for the exact numerical value that it precedes, the exact numerical value±5%, as well as all other numerical values that are near to or approximately equal to that numerical value. Unless otherwise indicated a particular numerical value is included in “about” a specifically recited numerical value where the particular numerical value provides the substantial equivalent of the specifically recited numerical value in the context in which the specifically recited numerical value is presented. For example, a statement that something has the numerical value of “about 10” is to be interpreted as: the set of statements:
in some embodiments the numerical value is 10;
in some embodiments the numerical value is in the range of 9.5 to 10.5; and if from the context the person of ordinary skill in the art would understand that values within a certain range are substantially equivalent to 10 because the values with the range would be understood to provide substantially the same result as the value 10 then “about 10” also includes:
in some embodiments the numerical value is in the range of C to D where C and D are respectively lower and upper endpoints of the range that encompasses all of those values that provide a substantial equivalent to the value 10

Specific examples of systems, methods and apparatus have been described herein for purposes of illustration. These are only examples. The technology provided herein can be applied to systems other than the example systems described above. Many alterations, modifications, additions, omissions, and permutations are possible within the practice of this invention. This invention includes variations on described embodiments that would be apparent to the skilled addressee, including variations obtained by: replacing features, elements and/or acts with equivalent features, elements and/or acts; mixing and matching of features, elements and/or acts from different embodiments; combining features, elements and/or acts from embodiments as described herein with features, elements and/or acts of other technology, and/or omitting combining features, elements and/or acts from described embodiments.

As will be apparent to those of skill in the art upon reading this disclosure, each of the individual embodiments described and illustrated herein has discrete components and features which may be readily separated from or combined with the features of any other described embodiment(s) without departing from the scope of the present invention.

Any aspects described above in reference to apparatus may also apply to methods and vice versa.

Any recited method can be carried out in the order of events recited or in any other order which is logically possible. For example, while processes or blocks are presented in a given order, alternative examples may pdalyerform routines having steps, or employ systems having blocks, in a different order, and some processes or blocks may be deleted, moved, added, subdivided, combined, and/or modified to provide alternative or subcombinations. Each of these processes or blocks may be implemented in a variety of different ways. Also, while processes or blocks are at times shown as being performed in series, these processes or blocks may instead be performed in parallel, simultaneously or at different times.

Various features are described herein as being present in “some embodiments”. Such features are not mandatory and may not be present in all embodiments. Embodiments of the invention may include zero, any one or any combination of two or more of such features. All possible combinations of such features are contemplated by this disclosure even where such features are shown in different drawings and/or described in different sections or paragraphs. This is limited only to the extent that certain ones of such features are incompatible with other ones of such features in the sense that it would be impossible for a person of ordinary skill in the art to construct a practical embodiment that combines such incompatible features. Consequently, the description that “some embodiments” possess feature A and “some embodiments” possess feature B should be interpreted as an express indication that the inventors also contemplate embodiments which combine features A and B (unless the description states otherwise or features A and B are fundamentally incompatible). This is the case even if features A and B are illustrated in different drawings and/or mentioned in different paragraphs, sections or sentences.

It is therefore intended that the following appended claims and claims hereafter introduced are interpreted to include all such modifications, permutations, additions, omissions, and sub-combinations as may reasonably be inferred. The scope of the claims should not be limited by the preferred embodiments set forth in the examples, but should be given the broadest interpretation consistent with the description as a whole.

What is claimed is:

1. A method for operating a semiconductor switching device having a gate capacitance to switch the device from a starting steady state to an ending steady state that is different from the starting steady state, the method comprising:
applying a first gate-driving voltage pulse to a gate of the device when the device is in the starting steady state, the first voltage pulse having a first effective amplitude a first pulse duration t_{A};
applying a second gate-driving voltage pulse to the gate after applying the first gate driving pulse, the second gate-driving voltage pulse having a second effective amplitude and a second pulse duration,
wherein the second voltage pulse is applied during a transition of the device between the starting steady state and the ending steady state.

2. The method of claim 1 wherein the first effective amplitude crosses from a starting state value that is below a threshold voltage Vₜₕ associated with the device to a first pulse value that is above the threshold voltage Vₜₕ.

3. The method of claim 1 wherein the second gate-driving voltage pulse has a second effective amplitude that crosses from an intermediate value that is below the threshold voltage Vₜₕ to a second pulse value that is above the threshold voltage Vₜₕ.

4. The method of claim 1 wherein the first effective amplitude is from a starting state value that is above a threshold voltage Vₜₕ associated with the device to a first pulse value that is below the threshold voltage Vₜₕ.

5. The method of claim 1 wherein the second gate-driving voltage pulse has a second effective amplitude that crosses from an intermediate value that is above the threshold voltage Vₜₕ to a second pulse value that is below the threshold voltage Vₜₕ.

6. The method of claim 3 wherein the intermediate value is about equal to the starting state value.

7. The method of claim 1 wherein the first pulse duration t_{A} is less than a time that it takes for the device to reach the ending steady state.

8. The method of claim 1 wherein the second gate-driving pulse has a duration that is sufficiently long for the device to reach the ending steady state during the second gate-driving pulse.

9. The method of claim 1 comprising maintaining the gate-driving voltage at an intermediate value for a period of time t_{B} after a conclusion of the first gate-driving pulse and before applying the second gate-driving voltage pulse.

10. The method of claim 9 wherein the second gate-driving voltage pulse has a second effective amplitude that crosses from the intermediate value that is below the threshold voltage Vₜₕ to a second pulse value that is above the threshold voltage Vₜₕ.

11. The method of claim 9 wherein the second gate-driving voltage pulse has a second effective amplitude that crosses from the intermediate value that is above the threshold voltage Vₜₕ to a second pulse value that is below the threshold voltage Vₜₕ.

12. The method of claim 9 wherein the intermediate value is the same at the starting state value.

13. The method of claim 1 wherein the first effective amplitude is the same as the second effective amplitude.

14. The method of claim 1, wherein the method is applied to a turn-ON operation, the device is non-conducting (e.g. between drain and source) in the starting steady state, the device is conducting (e.g. between drain and source) in the ending steady state, the starting state value and the intermediate value are less than the threshold voltage Vₜₕ and the first pulse value and the second pulse value are greater than the threshold voltage Vₜₕ.

15. The method of claim 1, wherein the method is applied to a turn-OFF operation, the device is conducting (e.g. between drain and source) in the starting steady state, the device is non-conducting (e.g. between drain and source) in the ending steady state, the starting state value and the intermediate value are greater than the threshold voltage Vₜₕ and the first pulse value and the second pulse value are less than the threshold voltage Vₜₕ.

16. The method of claim 1 comprising applying one or more additional gate-driving voltage pulses to the gate after applying the first gate driving pulse and prior to applying the second gate driving pulse.

17. The method of claim 16 wherein the one or more additional gate-driving pulses have the same pulse parameters (e.g. amplitude and duration) as the first pulse.

18. The method of claim 16 wherein at least one of the one or more additional gate-driving pulses has different pulse parameters (e.g. amplitude and duration) as the first pulse.

19. The method of claim 16 wherein temporal pulse-spacing between the first pulse, the one or more additional pulses and the second pulse is the same.

20. A circuit for operating a semiconductor switching device having a gate capacitance to switch the device from a starting steady state to an ending steady state that is different from the starting steady state, the circuit comprising:
a gate-control voltage source connected to a gate of the transistor by an electrically conductive (e.g. metal) connection between an output of the gate-control voltage source and the gate,
a controller connected to the gate-control voltage source, the controller configured to:
cause the gate-control voltage source to apply a first gate-driving voltage pulse to a gate of the device when the device is in the starting steady state, the first voltage pulse having a first effective amplitude a first pulse duration t_{A};
cause the gate-control voltage source to apply a second gate-driving voltage pulse to the gate after applying the first gate driving pulse, the second gate-driving voltage pulse having a second effective amplitude and a second pulse duration;
wherein the second voltage pulse is applied during a transition of the device between the starting steady state and the ending steady state.
